(19) United States
(12) Patent Application Publication
(10) Pub. No.: US 2024/0397227 A1
(43) Pub. Date: Nov. 28, 2024

(54) SOLID-STATE IMAGING DEVICE, METHOD FOR MANUFACTURING SOLID-STATE IMAGING DEVICE, AND ELECTRONIC APPARATUS

(71) Applicant: Brillnics Singapore Pte. Ltd., Singapore (SG)

(72) Inventors: Kazuya MORI, Tokyo (JP); Ken MIYAUCHI, Tokyo (JP); Hirofumi ABE, Tokyo (JP); Heng Yin CHEN, Tokyo (JP); HT CHANG, Zhubei City (TW)

(21) Appl. No.: 18/673,009

(22) Filed: May 23, 2024

(30) Foreign Application Priority Data
May 23, 2023 (JP) 2023-084853

(51) Int. Cl. H04N 25/77; H01L 27/146; H04N 25/11; H04N 25/53; H04N 25/78

(52) U.S. Cl. CPC H04N 25/77; H01L 27/14627; H04N 25/11; H04N 25/53; H04N 25/78

(57) ABSTRACT

Provided are a solid-state imaging device, a method for manufacturing a solid-state imaging device and an electronic apparatus that are capable of achieving maximized photo-responsiveness, ensuring low optical SNR in addition to reproducibility, and further reducing the pixel size, thereby efficiently improving performance factors such as the dynamic range, responsiveness, and resolution. Large-sized microlenses ML are allocated to color filters having high transparency (W), and small-sized microlenses ML are allocated to color filters having low transparency (B, R). The microlenses ML are non-uniform. The color filters underlying the large-sized microlenses ML need to be made from a highly transparent material.

### CROSS-REFERENCE TO RELATED APPLICATIONS

This application is based on and claims the benefit of priority from Japanese Patent Application Serial No. 2023-084853 (filed on May 23, 2023), the contents of which are incorporated herein.

### TECHNICAL FIELD

The present disclosure relates to a solid-state imaging device, a method for manufacturing a solid-state imaging device, and an electronic apparatus.

### BACKGROUND

Solid-state imaging devices (image sensors) including photoelectric conversion elements for detecting light and generating charges are embodied as complementary metal oxide semiconductor (CMOS) image sensors, which have been in practical use. The CMOS image sensors have been widely applied in various types of electronic apparatuses such as digital cameras, video cameras, surveillance cameras, medical endoscopes, personal computers (PCs), mobile phones and other portable terminals (mobile devices) as their parts.

The CMOS image sensors include, for each pixel, a photodiode (a photoelectric conversion element) and a floating diffusion (FD) amplifier having a floating diffusion (FD). The mainstream design of the reading operation in the CMOS image sensors is a column parallel output processing of selecting one of the rows in the pixel array and reading the pixels in the selected row simultaneously in the column output direction.

Each pixel of the CMOS image sensor generally includes, for one photodiode for example, four active elements: a transfer transistor serving as a transfer element; a reset transistor serving as a reset element; a source follower transistor serving as a source follower element (an amplification element); and a selection transistor serving as a selection element.

Common CMOS image sensors capture color images using three primary color filters for red (R), green (G), and blue (B) or four complementary color filters for cyan, magenta, yellow, and green.

In general CMOS image sensors, pixels respectively have filters. The filters include red (R) filters that mainly transmit red light, green (Gr, Gb) filters that mainly transmit green light, and blue (B) filters that mainly transmit blue light. An R filter, a Gr filter, a Gb filter and a B filter, in total, four filters are arranged in a square geometry and forms a sub-pixel group, which is referred to as a unit RGB sub-pixel group or multi-pixel. The multi-pixels are arranged two-dimensionally.

Light incident on the CMOS image sensors goes through the filters before received by the photodiodes. The photodiodes receive light having wavelengths (380 nm to 1,100 nm) within a region wider than the region of wavelengths visible to the human eye (380 nm to approximately 780 nm) and produce signal charges. Therefore, the photodiodes may suffer from errors produced by infrared light and thus have reduced color reproduction quality. Accordingly, it is a general practice to eliminate infrared light using infrared cut filters (IR cut filters).

RGB pixels with IR cut filters can achieve favorable color reproduction quality for visible light with high saturation light intensity and improved dynamic range. Instead of IR filters, white (W) or clear pixels can make highly sensitive cut filters for visible to near infrared wavelength ranges (see, for example, S. Kawada, S. Sakai, N. Akahane, R. Kuroda, and S. Sugawa, “Wide dynamic range checkerboard color CMOS image sensor with IR-Cut RGB and visible-near-IR pixels,” SENSORS, 2009, IEEE, 2009, pp. 1648-1651, doi: 10.1109/ICSENS.2009.5398511).

W filters are by far more responsive to visible light than other filters such as R, G and B filters. Therefore, by applying the white/clear filter technology to a color matrix, improved photo-responsiveness performance and enhanced performance under low illuminance can be accomplished.

FIG. 1 shows photo-responsive characteristics for a color matrix including various colors of W, R, G and B.

As can be seen from FIG. 1, when visible light is incident on a color matrix, the saturation point is limited by a high-transmissivity color filter (CF) of the color matrix. Therefore, by enhancing the saturation point of only the W and G filters, the dynamic range (DR) can be improved without requiring an increase in pixel size.

One of the approaches applied to increase the dynamic range, a lateral overflow integration capacitor (LOFIC) can be proposed.

In recent years, the increase in number of pixels in CMOS image sensors lead to an enhanced demand for a reduction in pixel size. To deal with this demand, multiple-pixel sharing technique has been proposed, according to which one floating diffusion FD, one reset transistor, one source follower transistor and one selection transistor are shared between a plurality of photodiodes and between a plurality of transfer transistors (see, for example, Japanese Patent Application Publications Nos. 2007-81033 (“the '033 Publication”) and 2013-627895 (“the '895 Publication”)).

The '033 Publication discloses an example of pixels of a CMOS image sensor having a two-pixel sharing configuration in which one floating diffusion FD, one reset transistor, one source follower transistor, and one selection transistor are shared by two sets of a photodiode and a transfer transistor.

The '895 Publication discloses an example of pixels of a CMOS image sensor having a four-pixel sharing configuration in which one floating diffusion FD, one reset transistor, one source follower transistor, and one selection transistor are shared by four sets of a photodiode and a transfer transistor.

A sharing pixel PXL1 has a rectangular region RCT1 where the elements are formed. The rectangular region RCT1 can be divided into a central region CTAR1 positioned in the center, and a first region FSAR1 and a second region SCAR1 sandwiching the central region CTAR1 therebetween (in the Y direction). The layout of the sharing pixel is basically as follows. A floating diffusion FD is arranged at the center of the element formation region, and photoelectric conversion elements or photodiodes PD are radially arranged around the floating diffusion FD.

For example, according to a two-pixel sharing configuration, in the central region CTAR1, the floating diffusion FD is formed in the X- and Y-direction-wise central portion thereof, the reset transistor RST-Tr is formed on the right side of the floating diffusion FD in the X direction, and the source follower transistor SF-Tr and the selection transistor SEL-Tr are formed on the left side of the floating diffusion FD in the X direction. The relative positions represented by the terms such as left and right can be only example and modified in any other manners than the illustrated example.

A first photodiode PD0 and a first transfer transistor TG0-Tr are adjacent to each other in the first region FSAR1. The first transfer transistor TG0-Tr is shaped like a rectangle, arranged closer to the central region CTAR1, and connected to the floating diffusion FD.

In the second region SCAR1, a second photodiode PD1 and a second transfer transistor TG1-Tr are formed. The second transfer transistor TG1-Tr is arranged closer to the central region CTAR1 and connected to the floating diffusion FD.

According to the above-described configurations, every two or four pixels can share their pixel components, so that the photodiode PD in each pixel can have a maximized size. This can contribute to reduce the size of the pixels while the sensitivity and well capacity remain unchanged.

Since the floating diffusion FD is shared by two or more photodiodes PDs, the deep trench isolation (DTI) technique is applied to prevent color signal cross-talk between the photodiodes PDs. Beneath the region where the shared FD is formed, the sub-deep trench isolation (sub-DTI) technique is applied in place of the full deep trench isolation (full-DTI).

The various types of CMOS image sensors described above respectively have the following advantages and disadvantages.

W filters are by far more responsive to visible light than other filters such as R, G and B filters. Therefore, by applying the white/clear filter technology to a color matrix, improved responsiveness performance and enhanced performance under low illuminance can be accomplished. When the CMOS image sensor with the while/clear filter technology is actually used under strong light, however, the white saturated signal is first clipped in the corresponding ADC code. After this, color reproduction collapses before the other signals such as R, G, and B signals are saturated, and the difference in saturation point results in poor performance under high illuminance.

Wide dynamic range (DR) CMOS image sensors, to which the FD sharing LOFIC technology is applied, have demonstrated good color reproduction and high sensitivity in the visible wavelength band. The FD sharing LOFIC technology can provide for a minimized pixel size and an increased full well capacity for one of the PDs sharing the FD. In other words, by having the proposed FD sharing PD layout and overflow direction control, the pixel circuit can achieve further reduction in pixel size as well as the HDR concept.

The following describes an example of color filter allocation that can optimize the saturation point. High-saturation PDs are allocated to high-transparency filters such as W filters, so that their own saturation point is enhanced. On the other hand, low-saturation PDs are allocated to low-transparency filters such as R/B filters.

In the case of dual size microlenses ML, large- and small-sized PDs are combined in the pixel, to achieve photo response for a range of extremely low illuminance to extremely high illuminance.

Single-chip wide dynamic range (DR) CMOS image sensors, to which LOFIC-based saturation point optimization technology is applied, have demonstrated good color reproduction and high sensitivity in the visible wavelength band. CMOS image sensors employing the LOFIC architecture have optimized capacitance value of each color pixel depending on its sensitivity in order to achieve maximized dynamic range.

CMOS image sensors employing the pixel size reduction technique and HDR technology have pixel circuits where the FD-shared PD layout and overflow direction control are applied. Although this allows further reduction in pixel size, it is difficult to hold overflow signal charges from the respective photodiodes PDs at the floating diffusion FD (FD node) as the LOFIC configuration is used for the HDR.

The following further discusses issues related to the pixel size and crosstalk. According to the above-described two- or four-pixel sharing configuration, every two or four pixels can share their pixel components, so that the photodiode PD in each pixel can have a maximized size. This can contribute to reduce the pixel size while the sensitivity and well capacity remain unchanged.

In the case of the four-pixel sharing configuration, however, the floating diffusion FD has a large area. This disadvantageously increases the capacitance of the floating diffusion FD, which lowers the conversion gain and increases the noise.

In the sharing pixel, the photodiodes PD are basically radially arranged around the floating diffusion FD. Requiring electrical connection, the reset transistor RST-Tr is connected to the floating diffusion FD of a different node formed in a neighboring region in the pixel. This in turn increases the junction capacitance and the wiring capacitance for the electrical connection, which disadvantageously increases the capacitance (Cfd) of the FD node, reduces the conversion gain and compromises the noise characteristics.

Generally, the signal (overflow charges) exceeding the charges that can be stored on a certain photodiode PD may flow into adjacent pixels, which can result in mixing of charges (causing a false signal). To prevent this, the overflow charges are guided to flow into the connected floating diffusion FD before leaking out into adjacent pixels. When this configuration is applied, a false signal may be still generated while the charges in the floating diffusion FD are being read out. This is because charges may leak into the floating diffusion FD from the pixels that share the floating diffusion. Taking the Bayer array as an example, overflow charges of the G signal may leak while the R signal is being read out. In this case, the charges may mix together at the floating diffusion FD serving as an output node.

Conventional CMOS image sensors with the sharing configuration described above encounter difficulties in employing white in the color matrix. Specifically, the photo-responsiveness can hardly be maximized, low optical SNR can hardly be achieved in addition to reproducibility. Due to these technical limitations, it is difficult to further reduce the pixel size.

### SUMMARY

An object of the present disclosure is to provide a solid-state imaging device, a method for manufacturing a solid-state imaging device and an electronic apparatus that are capable of not only reducing the size of the pixels while keeping the sensitivity and well capacity unchanged but also preventing an increase in junction capacitance and wiring capacitance, preventing an increase in the capacitance of the floating diffusion serving as an output node, preventing a drop in conversion gain, and eventually achieving improved noise characteristics, and also preventing the charges of different pixels from mixing together at the floating diffusion. Another object of the present disclosure is to provide a solid-state imaging device, a method for manufacturing a solid-state imaging device and an electronic apparatus that are capable of achieving maximized photo-responsiveness, ensuring low optical SNR in addition to reproducibility, and further reducing the pixel size, thereby efficiently improving important performance factors such as the dynamic range, responsiveness, and resolution.

A first aspect of the present disclosure provides a solid-state imaging device including a pixel part having an array of pixels arranged therein, each of the pixels including a photoelectric conversion part and being configured to perform photoelectric conversion on light incident thereon. In the pixel part, at least two adjacent pixels of the pixels form a pixel unit. A first pixel of the pixel unit includes: a first transmission filter having a predetermined transparency, the first transmission filter being provided on a light incidence path leading to a light incidence surface of a corresponding photoelectric conversion part; and a first microlens for redirecting incident light toward the light incidence surface of the corresponding photoelectric conversion part via the first transmission filter. A second pixel of the pixel unit includes: a second transmission filter having a higher transparency than the first transmission filter, the second transmission filter being provided on a light incidence path leading to a light incidence surface of a corresponding photoelectric conversion part; and a second microlens for redirecting incident light toward the light incidence surface of the corresponding photoelectric conversion part via the second transmission filter. A second incident light redirecting region handled by the second microlens is greater (larger) than a first incident light redirecting region handled by the first microlens.

A second aspect of the present disclosure provides a method for manufacturing a solid-state imaging device including a pixel part having an array of pixels arranged therein, each of the pixels including a photoelectric conversion part and being configured to perform photoelectric conversion on light incident thereon. In the pixel part, at least two adjacent pixels of the pixels form a pixel unit. A first pixel of the pixel unit includes: a first transmission filter having a predetermined transparency, the first transmission filter being provided on a light incidence path leading to a light incidence surface of a corresponding photoelectric conversion part; and a first microlens for redirecting incident light toward the light incidence surface of the corresponding photoelectric conversion part via the first transmission filter. A second pixel of the pixel unit includes: a second transmission filter having a higher transparency than the first transmission filter, the second transmission filter being provided on a light incidence path leading to a light incidence surface of a corresponding photoelectric conversion part; and a second microlens for redirecting incident light toward the light incidence surface of the corresponding photoelectric conversion part via the second transmission filter. A second incident light redirecting region handled by the second microlens is greater than a first incident light redirecting region handled by the first microlens.

A third aspect of the present disclosure provides an electronic apparatus including: a solid-state imaging device; and an optical system for forming a subject image on the solid-state imaging device. The solid-state imaging device includes a pixel part having an array of pixels arranged therein, each of the pixels including a photoelectric conversion part and being configured to perform photoelectric conversion on light incident thereon. In the pixel part, at least two adjacent pixels of the pixels form a pixel unit. A first pixel of the pixel unit includes: a first transmission filter having a predetermined transparency, the first transmission filter being provided on a light incidence path leading to a light incidence surface of a corresponding photoelectric conversion part; and a first microlens for redirecting incident light toward the light incidence surface of the corresponding photoelectric conversion part via the first transmission filter. A second pixel of the pixel unit includes: a second transmission filter having a higher transparency than the first transmission filter, the second transmission filter being provided on a light incidence path leading to a light incidence surface of a corresponding photoelectric conversion part; and a second microlens for redirecting incident light toward the light incidence surface of the corresponding photoelectric conversion part via the second transmission filter. A second incident light redirecting region handled by the second microlens is greater (larger) than a first incident light redirecting region handled by the first microlens.

### Advantageous Effects

The present disclosure can not only reduce the size of the pixels while keeping the sensitivity and full well capacity unchanged but also prevent an increase in junction capacitance and wiring capacitance, prevent an increase in the capacitance of the floating diffusion serving as an output node, prevent a drop in conversion gain and eventually achieve improved noise characteristics, and also prevent the charges of different pixels from mixing together at the floating diffusion. The present disclosure can achieve maximized photo-responsiveness, ensure low optical SNR in addition to reproducibility, and further reduce the pixel size, thereby efficiently improving important performance factors such as the dynamic range, responsiveness, and resolution.

### BRIEF DESCRIPTION OF THE DRAWINGS

FIG. 1 shows photo-responsive characteristics for a color matrix of various colors including W, R, G and B.

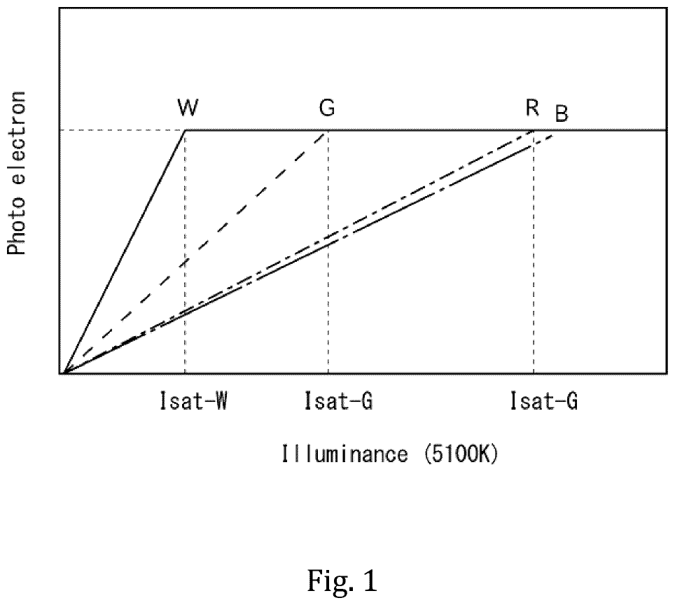

FIG. 2 is a block diagram showing an example configuration of a solid-state imaging device according to a first embodiment of the present disclosure.

FIG. 3 is a circuit diagram showing an example of pixels of the solid-state imaging device relating to the first embodiment of the present disclosure.

FIG. 4 shows an example of the array of pixels having a group of non-uniformly sized microlenses in the pixel part of the solid-state imaging device relating to the first embodiment of the present disclosure and also showing a comparative example of an array of pixels having a group of uniformly sized microlenses.

FIG. 5 includes sets of plan and simplified sectional views showing the array of pixels having a group of non-uniformly sized microlenses in the pixel part of the solid-state imaging device relating to the first embodiment of the present disclosure, specifically, large-sized microlenses provided for the purpose of improved response, as compared to an array of pixels having a group of equally-sized microlenses.

FIG. 6 shows an example case where the second microlens is shaped like an octahedron, which is selected from various polyhedrons.

FIG. 7 is a circuit diagram showing an example of a sharing pixel of a solid-state imaging device relating to a second embodiment of the present disclosure.

FIG. 8 shows an example of a read-out operation applicable to the sharing pixel of the solid-state imaging device relating to the second embodiment of the present disclosure, showing an example of a circuitry of the sharing pixel, a timing chart and potential transition in relation to each other.

FIG. 9 describes the photo charge state in the FD-shared PDs in relation to potential transition.

FIG. 10 is used to illustrate an example of photo response in a RWWB (RCCB) configuration with a shared FD structure and color matrix interpolation.

FIG. 11 is used to illustrate the advantageous effects achieved by the solid-state imaging device relating to the second embodiment.

FIG. 12 is a circuit diagram showing an example of a sharing pixel of a solid-state imaging device relating to a third embodiment of the present invention.

FIG. 13 shows examples of a color matrix for 2×2 FD-shared pixels.

FIG. 14 shows examples of a color matrix where W-IR-B-R pixels are arranged in a 2×2 square pattern.

FIG. 15 shows an example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel.

FIG. 16 shows an example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel.

FIG. 17 presents a timing chart illustrating an example of a four-sharing PD binning read-out operation with LOFIC and SEHDR being partially utilized applicable to the sharing pixel of the solid-state imaging device relating to the third embodiment of the present disclosure, in relation with an example of the reading circuit of the sharing pixel.

FIG. 18 shows an example of a read-out operation with SEHDR and with LOFIC being partially utilized applicable to the solid-state imaging device relating to the third embodiment of the present disclosure.

FIG. 19 shows another example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel.

FIG. 20 shows another example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel.

FIG. 21 is used to illustrate the advantageous effects achieved by the solid-state imaging device relating to the third embodiment.

FIG. 22 shows an example configuration of an electronic apparatus to which the solid-state imaging devices relating to the embodiments of the present disclosure can be applied.

### DESCRIPTION OF THE PREFERRED EMBODIMENTS

Embodiments of the present disclosure will be hereinafter described with reference to the drawings.

### First Embodiment

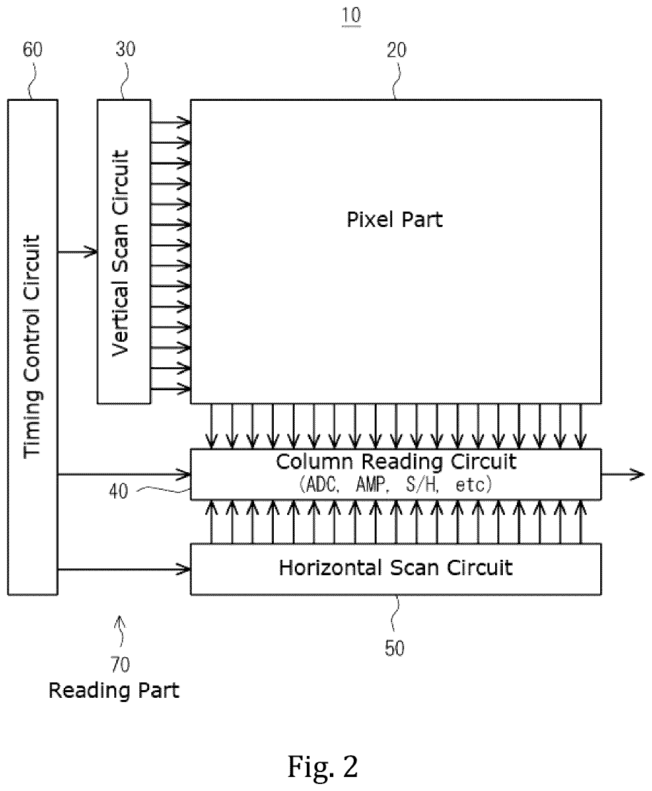

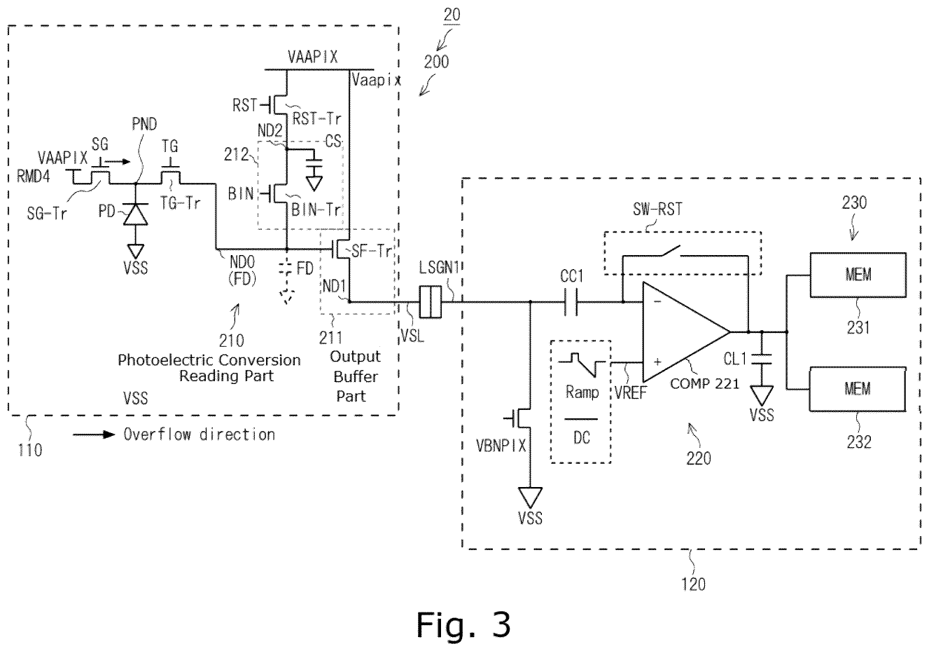

FIG. 2 is a block diagram showing an example configuration of a solid-state imaging device relating to a first embodiment of the present disclosure. FIG. 3 is a circuit diagram showing an example of the pixels of the solid-state imaging device relating to the first embodiment of the present disclosure. In this embodiment, a solid-state imaging device 10 is constituted by, for example, a CMOS image sensor.

As shown in FIG. 2, the solid-state imaging device 10 is constituted mainly by a pixel part 20 serving as an image capturing part, a vertical scanning circuit (a row scanning circuit) 30, a reading circuit (a column reading circuit) 40, a horizontal scanning circuit (a column scanning circuit) 50, and a timing control circuit 60. Among these components, for example, the vertical scanning circuit 30, the reading circuit 40, the horizontal scanning circuit 50, and the timing control circuit 60 constitute a reading part 70 for reading out pixel signals.

The pixel of the solid-state imaging device 10 relating to the present embodiment has the following characteristic features to not only reduce the size of the pixels while the sensitivity and full well capacity remain unchanged but also prevent an increase in junction capacitance and wiring capacitance, prevent an increase in capacitance of the floating diffusion serving as an output node to prevent a drop in conversion gain, and eventually achieve improved noise characteristics, and to secure maximized photo-responsiveness, to ensure low optical SNR in addition to reproducibility, and to further reduce pixel size, thereby efficiently improving important performance factors such as the dynamic range, responsiveness, and resolution. The solid-state imaging device 10 relating to the first embodiment includes non-uniform microlenses ML. Specifically, large-sized microlenses MLL are allocated to high-transparency (high-transmittance) color filters, for example, (W) filters, and small-sized microlenses MLS are allocated to low-transparency color filters, for example, visible-light color filters (B, R). The color filters underlying the large-sized microlenses MLL need to be made from a highly transparent material.

The following first describes the configurations and functions of the pixel part of the solid-state imaging device 10 relating to the first embodiment, for example, the structure of the pixel, and then moves onto an overall description of the characteristic features the pixel and the color filer matrix of the pixel part.

### <Overview of Components of Solid-State Imaging Device 10 Relating to First Embodiment Such as Pixel>

The pixels 200 relating to the first embodiment each include a photoelectric conversion reading part 210, an AD converting part 220, and a memory part 230, as shown in FIG. 3. The pixel part 20 relating to the first embodiment is configured as a stacked CMOS image sensor made up by a first substrate 110 and a second substrate 120. In the present example, as shown in FIG. 3, the photoelectric conversion reading part 210 is formed in the first substrate 110, and the AD converting part 220 and the memory part 230 are formed in the second substrate 120.

The photoelectric conversion reading part 210 of the pixel 200 includes a photodiode (a photoelectric conversion element) and an in-pixel amplifier. More specifically, the photoelectric conversion reading part 210 includes, for example, a photodiode PD, which is a photoelectric conversion element. For the photodiode PD, one transfer transistor TG-Tr serving as a transferring element, one reset transistor RST-Tr serving as a resetting element, one source follower transistor SF-Tr serving as a source follower element, one current transistor IC-Tr serving as a current source element, a shutter gate transistor SG-Tr serving as a shutter gate element, one floating diffusion FD serving as an output node ND0, and one reading node ND2 are provided. As described above, the photoelectric conversion reading part 210 of the pixel 200 relating to the first embodiment includes six transistors (6Tr), namely, the transfer transistor TG-Tr, the reset transistor RST-Tr, the source follower transistor SF-Tr, the current transistor IC-Tr, the storage transistor BIN-Tr and shutter gate transistor SG-Tr.

In the first embodiment, the source follower transistor SF-Tr, the current transistor IC-Tr, and the reading node ND1 together constitute an output buffer part 211.

In the photoelectric conversion reading part 210 relating to the first embodiment, the reading node ND1 of the output buffer part 211 is connected to the input part of the AD converting part 220. The photoelectric conversion reading part 210 converts the charges in the floating diffusion FD serving as an output node into a voltage signal at a level corresponding to the amount of the charges and outputs the voltage signal VSL to the AD converting part 220.

More specifically, the photoelectric conversion reading part 210 outputs, in a first comparing operation period PCMP1 of the AD converting part 220, a voltage signal VSL corresponding to the overflow charges overflowing from the photodiode PD, which is a photoelectric conversion element, to the floating diffusion FD serving as an output node in an integration period PI.

Furthermore, the photoelectric conversion reading part 210 outputs, in a second comparing operation period PCMP2 of the AD converting part 220, a voltage signal VSL corresponding to the charges stored in the photodiode PD that are transferred to the floating diffusion FD serving as an output node in a transfer period PT following the integration period PI. The photoelectric conversion reading part 210 outputs a read-out reset signal (signal voltage) (VRST) and a read-out signal (signal voltage) (VSIG), as a pixel signal, to the AD converting part 220 in the second comparing operation period PCMP2.

The photodiode PD generates signal charges (electrons) in an amount in accordance with the quantity of the incident light and stores the generated signal charges. Description will be hereinafter given of a case where the signal charges are electrons and each transistor is an n-type transistor. However, it is also possible that the signal charges are holes or each transistor is a p-type transistor. Further, this embodiment is also applicable to the case where a plurality of photodiodes and transfer transistors share the transistors.

The photodiode (PD) in each pixel 200 is a pinned photodiode (PPD). The substrate surface for forming the photodiode (PD) has a surface level due to dangling bonds or other defects. Therefore, a lot of charges (dark current) are generated due to heat energy, as a result of which the signals fail to be read out correctly. The pinned photodiodes (PPDs) have the charge storage part buried in the substrate, thereby reducing mixing of the dark current into the signals.

In the photoelectric conversion reading part 210, the transfer transistor TG-Tr is connected between the photodiode PD and the floating diffusion FD and controlled by a control signal TG applied to the gate thereof through a control line. The transfer transistor TG-Tr remains selected and in the conduction state during a transfer period PT in which the control signal TG is at the high (H) level, to transfer to the floating diffusion FD the charges (electrons) produced by the photoelectric conversion and then stored in the photodiode PD. After the photodiode PD and the floating diffusion FD are reset to a predetermined reset potential, the transfer transistor TG-Tr enters the non-conduction state with the control signal TG being set to the low (L) level and the photodiode PD enters an integration period PI. Under these circumstances, if the intensity of the incident light is very high (the amount of the incident light is very large), the charges above the full well capacity overflow into the floating diffusion FD as overflow charges through the overflow path under the transfer transistor TG-Tr.

The reset transistor RST-Tr is connected between the power supply line Vdd of the power supply voltage (sometimes may be referred to as “the power supply potential”) VDD and the floating diffusion FD and controlled by a control signal RST applied to the gate thereof through a control line. The reset transistor RST-Tr remains selected and in the conduction state during a reset period in which the control signal RST is at the H level, to reset the floating diffusion FD to the potential of the power supply line Vdd of the power supply voltage VDD.

The source follower transistor SF-Tr serving as a source follower element is connected at the source thereof to the reading node ND1, at the drain thereof to the power supply line Vdd, and at the gate thereof to the floating diffusion FD. The drain and source of the current transistor IC-Tr serving as a current source element are connected between the reading node ND1 and the reference potential VSS (for example, GND). The gate of the current transistor IC-Tr is connected to the feeding line of a control signal VBNPIX. The signal line LSGN1 between the reading node ND1 and the input part of the AD converting part 220 is driven by the current transistor IC-Tr serving as a current source element.

The shutter gate transistor SG-Tr serving as a shutter gate element is shown as a form of a charge release part that is configured to release undesired charges from the photodiode PD to a region different from the region of the floating diffusion FD serving as the output node if irregular and strong light enters the photodiode PD during the second comparing operation PCMP2 of the AD conversion.

The shutter gate transistor SG-Tr has a source and a drain connected to the charge storage part of the photodiode PD and the predetermined fixed potential VAAPIX, and is controlled by a control signal SG applied thereto the gate thereof through a control line. The shutter gate transistor SG-Tr remains selected and in the conduction state during the period in which the control signal SG is at the H level, to form an antiblooming path between the charge storage part of the photodiode PD and the predetermined fixed potential VAAPIX. In this way, unnecessary charges are released to the fixed potential VAAPIX.

The storage transistor BIN-Tr is connected between the floating diffusion FD and the reset transistor RST-Tr, and the storage capacitor CS is connected between a connection node ND2, which is between the storage transistor BIN-Tr and the reset transistor RST-Tr, and the reference potential VSS. The storage transistor BIN-Tr is controlled by a control signal BIN applied to the gate thereof through a control line. The storage transistor BIN-Tr remains selected and in the conduction state during a reset period in which the control signal BIN is at the H level so as to connect the floating diffusion FD and the storage capacitor CS.

As described above, the photoelectric conversion reading part 210 of the solid-state imaging device 10 relating to the first embodiment includes the photodiode PD, floating diffusion FD, transfer transistor TG-Tr, reset transistor RST-Tr, storage (binning (BIN)) transistor BIN-Tr, and source follower (SF) transistor SF-Tr.

The photodiode PD is formed by a pinned photodiode having a transfer transistor TG-Tr being connected to transfer charges to the floating diffusion FD. The reset transistor RST-Tr is connected to forcibly set the floating diffusion FD to a reset level (Vrst) before the charges are transferred. The electrons produced by the photoelectric conversion are stored in the photodiode PD and transferred to the floating diffusion FD via the transfer transistor TG-Tr.

The signals representing the stored photo charges can be read out within a single frame using the pairs of memories for the corresponding signals provided in column- or pixel-wise ADCs. Such multi-node multi-gain readout scheme can accomplish expanded dynamic range, so that signals can be reliably produced over a wide range from low illuminance (high gain) to bright light (low gain).

ADC conversion may occur for each signal corresponding to the stored photo charges, and at least two or more ADC conversions are available with different conversion gains. These digital codes can be linearized after post data processing.

The above has described the configurations and functions of the pixels of the solid-state imaging device 10 relating to the first embodiment. The following now provides an overview description of the characteristic features of the solid-state imaging device 10 relating to the first embodiment, such as the pixel and the color filter matrix of the pixel part.

### (Example Configuration of Pixel Part 20)

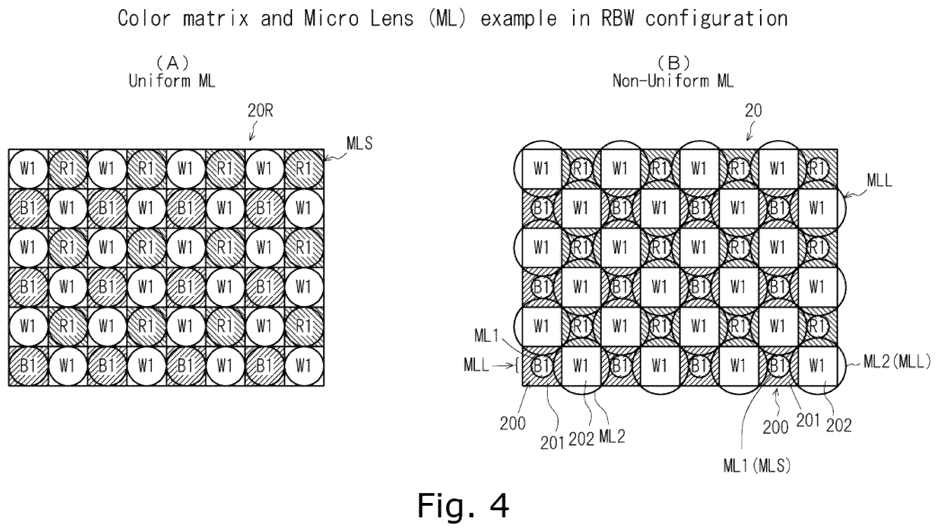

FIG. 4 includes views (A) and (B) showing an example of the array of pixels having a group of non-uniformly sized microlenses in the pixel part of the solid-state imaging device 10 relating to the first embodiment of the present disclosure and also showing a comparative example of an array of pixels having a group of uniformly sized microlenses. In FIG. 4, the view (A) shows an example of the array of pixels having a group of non-uniformly sized microlenses in the pixel part of the solid-state imaging device 10 relating to the first embodiment, and the view (B) shows, as a comparative example, an array of pixels having a group of uniformly sized microlenses. The example color matrices and microlenses (ML) shown in FIG. 4 have an RBW color matrix.

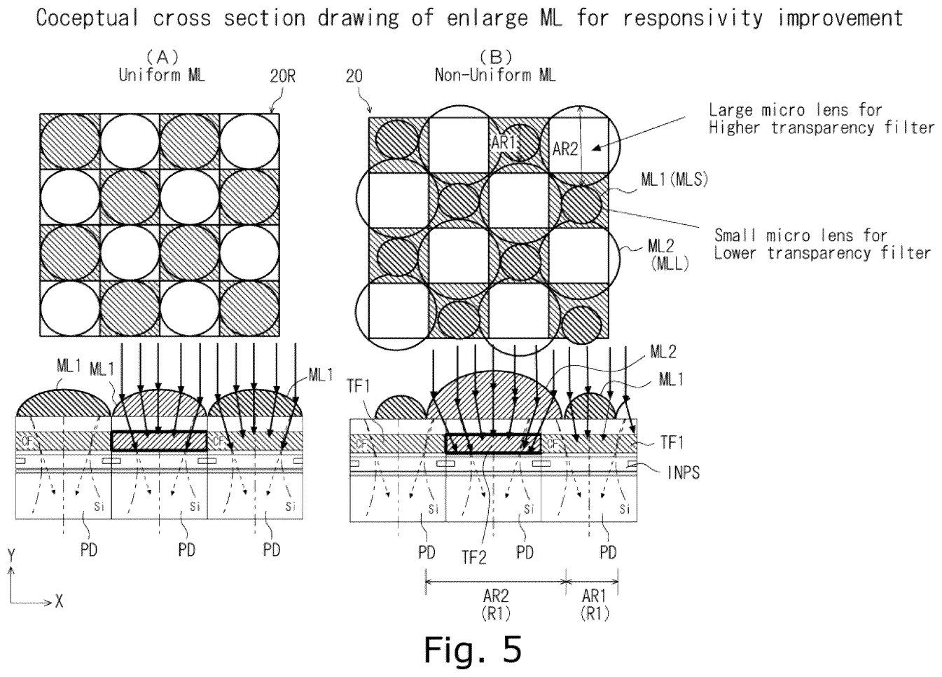

FIG. 5 includes sets of a plan view and a simplified sectional view ((A) and (B)) showing the array of pixels having a group of non-uniformly sized microlenses in the pixel part of the solid-state imaging device 10 relating to the first embodiment of the present disclosure, specifically, large-sized microlenses provided for the purpose of improved response, as compared to an array of pixels having a group of equally-sized microlenses. In FIG. 4, the view (A) shows an example of the array of pixels having a group of non-uniformly sized microlenses in the pixel part of the solid-state imaging device 10 relating to the first embodiment, and the view (B) shows, as a comparative example, an array of pixels having a group of uniformly sized microlenses. The example color matrices and microlenses (ML) shown in FIG. 4 have an RBW color matrix.

In the pixel part 20, a plurality of pixels 200 are arranged in a matrix of N rows and M columns. In a regular pixel part 20R, as shown in the view (A) in FIG. 5, the pixels all have an equal size and the microlenses configured to control light incident on the pixels are uniform.

In the pixel part 20 relating to the first embodiment, on the other hand, the array of pixels includes a group of non-uniformly sized microlenses (MLL and MLS).

More specifically, the pixel part 20 includes an array of pixels 200 each of which includes a photodiode PD serving as a photoelectric converting part and is configured to perform photoelectric conversion on light incident thereon. In the pixel part 20, at least two adjacent pixels 201 and 202 form a pixel unit PXU.

A first pixel 201 of the pixel unit PXU includes a first transmission filter TF1 having a predetermined transparency and located in a light incidence path leading to the light incidence surface INPS of a corresponding photodiode PD, and a first microlens ML1 (MLS) for redirecting the incident light toward the light incidence surface INPS of the corresponding photodiode PD via the first transmission filter TF1. The first transmission filter TF1 may have a lower transparency (transmittance) than a second transmission filter TF2 and thus can be an R filter or B filter for the visible light band.

A second pixel 202 of the pixel unit PXU includes a second transmission filter TF2 having a higher transparency than the first transmission filter TF1 and located in a light incidence path leading to the light incidence surface INPS of a corresponding photodiode PD, and a second microlens ML2 (MLL) for redirecting the incident light toward the light incidence surface of the corresponding photodiode PD via the second transmission filter TF2.

In the first embodiment, a second incident light redirecting region AR2 handled by the second microlens ML2 (MLL) is greater (larger) than a first incident light redirecting region AR1 handled by the first microlens ML1 (MLS).

Here, the term “an incident light redirecting region AR” may denote a region extending in the X direction within which a corresponding microlens ML can capture incident light, and/or a region extending in the X direction through which a corresponding microlens ML redirects incident light toward a corresponding photodiode PD.

In the first embodiment, the diameter R2 of the second microlens ML2 (MLL) is greater than the diameter R1 of the first microlens ML1 (MLS) in the direction parallel to the light incidence surface INPS of the photodiodes PD. In other words, in the first embodiment, the size of the microlenses ML can be determined by referring to their diameter R.

In the first embodiment, the second microlens ML2 (MLL) of the second pixel 202 radially extends, beyond a corresponding second pixel region, to a first pixel region adjacent to the second pixel 202. Referring to the views (B) in FIGS. 4 and 5, the second microlens ML2 (MLL) is shaped such that, when seen from above, its circular outer edge is positioned over the adjacent first pixel 201 having a smaller size.

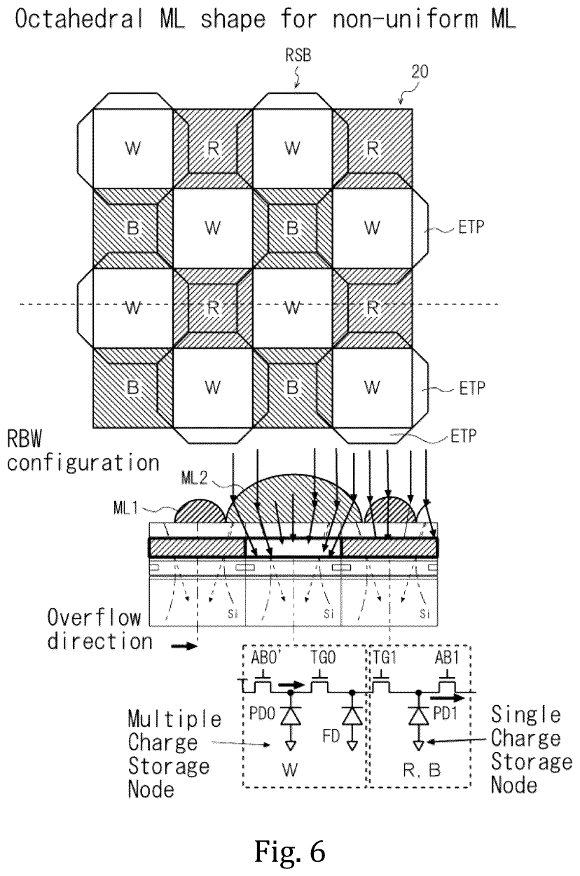

FIG. 6 shows an example case where the second microlens is shaped like an octahedron, which is selected from various polyhedrons. In the first embodiment, the second microlens ML2 (MLL) may be shaped like a polyhedron RSB (an octahedron in the example shown in FIG. 6) having extended portions ETP that can be equally extended in respective extending directions (the X and Y directions), as shown in FIG. 6.

In the first embodiment, a unit color matrix PCMTX is defined as a set of adjacent pixels, for example, the first and second pixels of at least two pixel units PXU. In the first embodiment, the unit color matrix PCMTX includes W (clear, mono) filters as the highly transparent second transmission filters to enhance responsiveness. Alternatively, the unit color matrix PCMTX may include IR filters as the second transmission filters to perform background light subtraction and/or specific optical imaging.

The following description is made with reference to FIGS. 2 and 3.

The AD converting part 220 of the pixel 200 compares the analog voltage signal VSL output from the photoelectric conversion reading part 210 against the referential voltage VREF, which has a ramp waveform varying with a predetermined gradient or a fixed voltage level, to convert the analog signal into a digital signal.

As shown in FIG. 3, the AD converting part 220 includes a comparator (COMP) 221, an output-side load capacitor CL1 and a reset switch SW-RST.

In the comparator 221, a first input terminal or inversion input terminal (−) receives the voltage signal VSL fed thereto, which is output from the output buffer part 211 of the photoelectric conversion reading part 210 to the signal line LSGN1, and a second input terminal or non-inversion input terminal (+) receives the referential voltage VREF fed thereto. The comparator 221 performs AD conversion (a comparing operation) of comparing the voltage signal VSL against the referential voltage VREF and outputting a digital comparison result signal SCMP.

The first input terminal or inversion input terminal (−) of the comparator 221 is connected to a coupling capacitor CC1. In this way, the output buffer part 211 of the photoelectric conversion reading part 210 formed on the first substrate 110 is AC coupled to the input part of the comparator 221 of the AD converting part 220 formed on the second substrate 120, so that the noise can be reduced and high SNR can be achieved when the illuminance is low.

As for the comparator 221, the reset switch SW-RST is connected between the output terminal and the first input terminal or inversion input terminal (−), and the load capacitor CL1 is connected between the output terminal and the reference potential VSS.

In the AD converting part 220, basically, the comparator 221 compares the analog signal (the potential VSL) read from the output buffer part 211 of the photoelectric conversion reading part 210 to the signal line LSGN1 against the referential voltage VREF, for example, a ramp signal RAMP that linearly changes with a certain gradient or has a slope waveform. During the comparison, a counter (not shown), which is provided for each column as is the comparator 221, is operating. The ramp signal RAMP having a ramp waveform and the value of the counter vary in a one-to-one correspondence, so that the voltage signal VSL is converted into a digital signal. Basically, the AD converting part 220 converts a change in voltage, in other words, a change in the referential voltage VREF (for example, the ramp signal RAMP) into a change in time, and counts the change in time at certain intervals (with certain clocks). In this way, a digital value is obtained. When the analog signal VSL and the ramp signal RAMP (the referential voltage VREF) cross each other, the output from the comparator 221 is inverted, the clock (not shown) input into the counter is stopped or the suspended clock (not shown) is input into the counter, and the value (data) of the counter at that timing is saved in the memory part 230. In this way, the AD conversion is completed. After the end of the above-described AD converting period, the data (signal) stored in the memory part 230 of each pixel 200 is output through the reading circuit 40 to a signal processing circuit (not shown) and subject to predetermined signal processing, so that a two-dimensional image is produced.

The memory part 230 is formed by an SRAM or DRAM, receives digital signals fed thereto, is compatible with photo conversion codes, and can be read by an external 10 buffer in the reading circuit 40 near the pixel array. In the present example, the memory part 230 includes two memories 231 and 232 connected to the output from the comparator 221.

The vertical scanning circuit 30 drives the photoelectric conversion reading part 210 of the pixel 200 through row-scanning control lines in shutter and reading rows, under the control of the timing control circuit 60. The vertical scanning circuit 30 feeds a referential voltage level VREF, which is set in accordance with the comparing operation, to the comparator 221 of each pixel 200, under the control of the timing control circuit 60. Further, the vertical scanning circuit 30 outputs, according to an address signal, row selection signals indicating the row addresses of the reading row from which signals are to be read out and the shutter row in which the charges stored in the photodiodes PD are to be reset.

The reading circuit 40 includes a plurality of column signal processing circuits (not shown) arranged corresponding to the column outputs of the pixel part 20, and the reading circuit 40 may be configured such that the plurality of column signal processing circuits can perform column parallel processing.

The reading circuit 40 may include a correlated double sampling (CDS) circuit, an analog-to-digital converter (ADC), an amplifier (AMP), a sample/hold (S/H) circuit, and the like.

The following now describes the advantageous effects of the solid-state imaging device 10 relating to the first embodiment.

### Advantageous Effects of First Embodiment

As described above, in the solid-state imaging device 10 relating to the first embodiment, the large-sized microlenses MLL are allocated to the high-transparency color filters, for example, the (W) filters, and the small-sized microlenses MLS are allocated to the low-transparency color filters, for example, the visible light (B, R) color filters. The microlenses ML have thus non-uniform sizes. The color filters underlying the large-sized microlenses MLL need to be made from a highly transparent material.

According to the above-described configuration, the saturation point of the underlying transparent (R-B) color matrix is limited by the characteristics of the W filter. The saturation point of the RB (W) filter configuration, where the W (clear) filter is provided to achieve higher transparency, is limited by the W filter. Therefore, the maximum illuminance, which normally contributes to achieve color reproducibility, may drop. If overflow charges are stored in the FD in the FD-sharing PDs, the PD having the highest transmittance can achieve increased full well capacity.

The first embodiment can achieve higher responsiveness and also accomplish higher SNR performance in low illuminance environment while an increased dynamic range can be obtained as well as excellent color reproducibility. In addition, the first embodiment can allow some of the pixel circuit components such as the FD and gain buffer to be shared among a plurality of PDs and achieve improved saturation, when compared with the conventional dual-size PD and LOFIC configurations, thereby enabling a smaller pixel size and higher resolution.

In the first embodiment, the full well capacity (FWC) of the PD that has the highest transmittance among the PDs sharing an FD can be expanded if overflow charges are accumulated. To completely expand the well capacity, which is determined by the Qpd, some overhead is required for the pixel size, but the first embodiment eliminates the need for such overhead. The solid-state imaging device 10 relating to the first embodiment can thus have high responsiveness, high SNR performance in low illuminance environment, high dynamic range and excellent color reproducibility, as described above.

### Second Embodiment

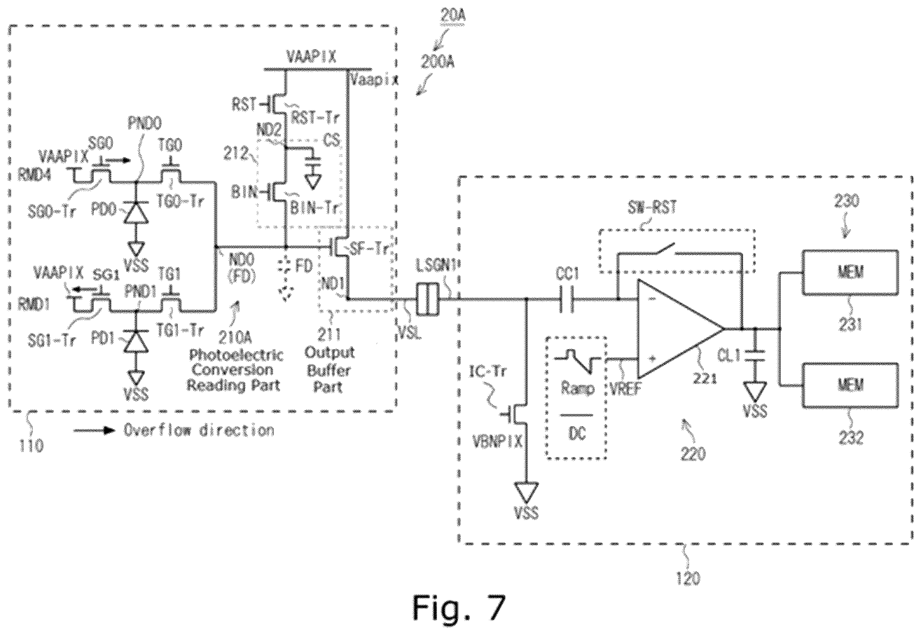

FIG. 7 is a circuit diagram showing an example of a sharing pixel of a solid-state imaging device relating to a second embodiment of the present disclosure.

A sharing pixel 200A of a solid-state imaging device 10A relating to the second embodiment differs from the pixel 200 of the solid-state imaging device 10 relating to the above-described first embodiment in the following points.

In the sharing pixel 200A of the solid-state imaging device 10A relating to the second embodiment, two photodiodes PD0 and PD1 share one floating diffusion FD. Specifically, the solid-state imaging device 10A relating to the second embodiment includes a first photodiode PD0 connected to a first transfer transistor TG0-Tr, a second photodiode PD1 connected to a second transfer transistor TG1-Tr, a floating diffusion FD connected to the first and second transfer transistors TG0-Tr and TG1-Tr, a first shutter gate transistor SG0-Tr serving as an anti-blooming gate connected to the first photodiode PD0, and a second shutter gate transistor SG1-Tr serving as an anti-blooming gate connected to the second photodiode PD1. In the sharing pixel 200A of the solid-state imaging device 10A relating to the second embodiment, a first saturation signal SAT0 from the first photodiode PD0 entirely overflows into the floating diffusion FD via the first transfer transistor TG0-Tr, and a second saturation signal SAT1 from the second photodiode PD1 is discharged through the second shutter gate transistor SG1-Tr.

According to the second embodiment, the solid-state imaging device 10A has pixels (or the pixel part 20) arranged in a matrix pattern in the pixel part 20, as will be described in detail below. The pixels are configured such that every two photoelectric conversion elements (photodiodes: PDs) and every two transfer elements (transfer transistors) share one floating diffusion FD serving as an output node and one source follower element (source follower transistor) constituting an output buffer. The sharing pixel of the solid-state imaging device 10A relating to the second embodiment has the following characteristic features to not only reduce the size of the pixels while the sensitivity and full well capacity remain unchanged but also prevent an increase in junction capacitance and wiring capacitance, prevent an increase in capacitance of the floating diffusion serving as an output node to prevent a drop in conversion gain, and eventually achieve improved noise characteristics, and secure maximized photo-responsiveness, ensure low optical SNR in addition to reproducibility, and further reduce pixel size, thereby efficiently improving important performance factors such as the dynamic range, responsiveness, and resolution.

The following first outlines characteristic components of the solid-state imaging device 10A relating to the second embodiment, such as the sharing pixel and the color filter matrix of the pixel part, and then moves onto detailed description of the configurations and functions such as the configuration of the sharing pixel and the array in order.

### <Overview of Characteristic Components of Solid-State Imaging Device 10A Relating to Second Embodiment, e.g., Sharing Pixel>

In the solid-state imaging device 10A relating to the second embodiment, the sharing pixel 200A has a shared FD structure including a first photodiode PD0 and a second photodiode PD1, and a first saturation signal saturated in the first photodiode PD0 is fully transferred to the floating diffusion FD (overflow). In the sharing pixel 200A, an overflow signal from the other PD or the second photodiode PD1 to the floating diffusion FD is released (discharged) to the drain via the shutter gate SG (AB) on the other side. Therefore, no overflow signal flows into the floating diffusion FD. While these components share the FD, no overflow signal mixing happens and signal crosstalk is thus prevented.

The photodiodes PD0 and PD1 each have two transfer gates connected thereto, so that the stored charges can be discharged to independently control the duration of integration. In addition, the overflow direction can be controlled so that the overflow signals do not mix at the floating diffusion FD, as mentioned above.

The sharing pixel 200A includes a floating diffusion FD shared between the first and second photodiodes PD0 and PD1, transfer transistors TG-Tr, a reset transistor RST-Tr, a binning (BIN) transistor BIN-Tr, and a source follower (SF) transistor SF-Tr.

The photodiodes PD (0,1) are each formed by a pinned photodiode having a transfer transistor TG-Tr being connected to transfer charges to the floating diffusion FD. The reset transistor RST-Tr is connected to forcibly set the floating diffusion FD to a reset level (Vrst) before the charges are transferred. The electrons produced by the photoelectric conversion are stored in the photodiodes PD and transferred to the floating diffusion FD via the transfer transistors TG-Tr.

A sequence of operations to read the pixel signal in the second embodiment may start with a PD read-out signal Qpd0, which is read first from the PDs. Subsequently, an overflow signal Qfd, which is read second and can be used as a storage node, follows. This can extend the total amount of photo charges to be processed. After this, a PD signal Qpd1 is read out, which is read second from the PDs. Thus, the total amount of photo charges is determined by the charges (Qpd1+Qfd) from the first photodiode PD0 and the charges Qpd1 from the second photodiode PD1.

The signals representing the stored photo charges can be read out within a single frame using a pair of memories for the corresponding signals provided in a column- or pixel-wise ADC. Such multi-node multi-gain readout scheme can accomplish extended dynamic range, so that signals can be reliably produced over a wide range from low illuminance (high gain) to bright light (low gain).

ADC conversion may occur for each signal corresponding to the stored photo charges, and at least two or more ADC conversions are available with different conversion gains. These digital codes can be linearized after post data processing.

In the sharing pixel 200A, one of the PDs can have a large full well capacitance (FWC). Therefore, a high-transmittance color filter is applied to the first photodiode PD0, from which the overflow photo charges are stored in the floating diffusion FD. A low-transmittance color filter is applied to the second photodiode PD1, which only stores a focused pixel PD in which corresponding photo charges are accumulated.

In this way, the first photodiode PD0 can achieve an enlarged maximum photo area, so that the signal ratio can remain unchanged due to high saturation.

The color matrix has an RGBW configuration typified as follows. The highest transmittance filter or the clear (W) filter can be allocated to the first photodiode PD0 to extend the signal response coverage, so that all signals from the photodiode PD0 can saturate. The low transmittance filter or the R or B filter can be assigned to the second photodiode PD1. Accordingly, the signal response coverage of the single photodiode PD0 can be sufficiently extended, to ensure color reproducibility for all pixels while significantly reducing the pixel size.

The microlenses respectively cover the photodiodes PD. Each microlens ML has a size optimized for the transmittance of a corresponding color filter. This is because the full well capacity of each of the PDs sharing a FD can be increased to a greater degree if the responsiveness increases.

Since the shared FD configuration is employed, the pixels can be formed above a back sided isolation (BSI) structure including a partially open full DTI, which can prevent color signal crosstalk between the photodiodes PDs.

The above has briefly described the characteristic features of the solid-state imaging device 10A relating to the second embodiment, such as the sharing pixel and the color filter matrix of the pixel part. The following now describes in order and in details the configurations and functions of the solid-state imaging device 10A relating to the second embodiment, such as the signal reading scheme, the configuration of the sharing pixel, and the array.

### <Example of Signal Reading Scheme>

The following now describes an example of how to read the signals in the solid-state imaging device 10A relating to the second embodiment.

In the solid-state imaging device 10A relating to the second embodiment, the pixel part 20A includes pixels, and each pixel includes a photoelectric conversion reading part 210A, an analog-to-digital (AD) converting part 220, and a memory part 230. The solid-state imaging device 10A is configured, for example, as a stacked CMOS image sensor. The solid-state imaging device 10A may be configured to be capable of operating in a global shutter mode. In the solid-state imaging device 10A relating to the second embodiment, as in the first embodiment, each pixel has an analog-to-digital (AD) converting function, and the AD converting part includes a comparator for comparing the voltage signal read from the photoelectric conversion reading part against a referential voltage to analog-to-digital (AD) convert the read-out voltage signal VSL and outputting a resulting digital comparison result signal.

Under the control of the reading part 70, the comparator performs a first comparing operation and a second comparing operation. The first comparing operation is designed to output a digital first comparison result signal obtained by processing the voltage signal corresponding to the overflow charges that overflow from the photodiode PD serving as the photoelectric conversion element to the output node (floating diffusion) in an integration (exposure) period. The second comparing operation is designed to output a digital second comparison result signal obtained by processing the voltage signal corresponding to the charges stored in the photodiode PD serving as the photoelectric conversion element that are transferred to the output node in a transfer period following the integration period.

If irregular and strong light enters the photodiode PD serving as the photoelectric conversion element during the second comparing operation, unnecessary charges may be released from the photodiode PD serving as the photoelectric conversion element to the region different from the floating diffusion FD region. For this purpose, the pixel relating to the present embodiment includes a shutter gate (SG) for preventing a change in the level of the floating diffusion. Such a change in the FD level may be caused if the charges overflow from the photoelectric conversion element to the floating diffusion FD. The shutter gate can prevent a change in the FD level even if irregular and strong light enters the photoelectric conversion element during the second comparing operation. Accordingly, the AD conversion can be successfully performed.

In the solid-state imaging device 10A relating to the second embodiment, the reading part 70 reads the pixel signal from the digital pixel and stores data resulting from the AD conversion in the following manner, in order to be capable of realizing the pixel that can widen the dynamic range by performing the reading in a predetermined mode while achieving a small size.

In the solid-state imaging device 10A, the comparator is configured to be capable of, under the control of the reading part 70, performing a comparing operation on read-out signals read in at least two different modes through different sequences of operations for reading performed on the charges stored in different photoelectric conversion elements. More specifically, the comparator is connected to a single photoelectric conversion reading part (pixel) in which two different photodiodes (photoelectric conversion elements) PD share a single floating diffusion FD, which serves as an output node, and is configured to be capable of performing a comparing operation on read-out signals read in at least two modes through different sequences of operations for reading performed on the charges stored on the different photodiodes PD in the same photoelectric conversion reading part. Alternatively, the comparator is connected to a selected one of a plurality of photoelectric conversion reading parts, each of which includes one or more (in the present example, two) photodiodes PDs, so that the single comparator is shared between the photoelectric conversion reading parts. In this way, the comparator is configured to be capable of performing a comparing operation on read-out signals read in at least two different modes through different sequences of operations for reading performed on the charges stored in the different photodiodes PD0 and PD1 in different photoelectric conversion reading parts.

In the present embodiment, the reading part 70 can read the pixel signals in at least two reading modes, which are selected from among at least four different reading modes: a first reading mode RMD1, a second reading mode RMD2, a third reading mode RMD3 and a fourth reading mode RMD4.

In the first reading mode RMD1, the reading part 70 can perform a second conversion gain reset reading operation LCGRRD of reading, in a reset reading period PRRD following a reset period PR, from the output buffer part, a read-out reset signal LCGVRST resulting from conversion performed with a second conversion gain (for example, low conversion gain: LCG) corresponding to a second amount of charges in the output node (floating diffusion) and performing a comparing operation at the comparator on the read-out reset signal LCGVRST. Furthermore, in the first reading mode RMD1, the reading part 70 can perform a second conversion gain reading operation LCGSRD of reading, in a reading period PRD following a transfer period PT after the reset reading period PRRD, from the output buffer part, a read-out signal LCGVSIG resulting from conversion performed with the second conversion gain corresponding to the second amount of charges in the output node and performing a comparing operation at the comparator on the read-out signal LCGVSIG.

In the first reading mode RMD1, the reading part 70 can perform a first conversion gain reset reading operation HCGRRD of reading, in the reset reading period PRRD following the reset period PR, from the output buffer part, a read-out reset signal HCGVRST resulting from conversion performed with a first conversion gain (for example, high conversion gain: HCG) corresponding to a first amount of charges in the output node (floating diffusion) and performing a comparing operation at the comparator on the read-out reset signal HCGVRST. Furthermore, in the first reading mode RMD1, the reading part 70 can perform a first conversion gain reading operation HCGSRD of reading, in the reading period PRD following the transfer period PT after the reset reading period PRRD, from the output buffer part, a read-out signal HCGVSIG resulting from conversion performed with the first conversion gain corresponding to the first amount of charges in the output node and performing a comparing operation at the comparator on the read-out signal HCGVSIG.

In the second reading mode RMD2, the reading part 70 can perform the second conversion gain reset reading operation LCGRRD of reading, in the reset reading period PRRD following the reset period PR, from the output buffer part, the second read-out reset signal LCGVRST resulting from conversion performed with the second conversion gain corresponding to the second amount of charges in the output node and performing a comparing operation at the comparator on the second read-out reset signal LCGVRST. Furthermore, in the second reading mode RMD2, the reading part 70 can use a gain switching part to switch the gain and perform the first conversion gain reset reading operation HCGRRD of reading, from the output buffer part, the first read-out reset signal HCGVRST resulting from conversion performed with the first conversion gain corresponding to the first amount of charges in the output node and performing a comparing operation at the comparator on the first read-out reset signal HCGVRST. Furthermore, in the second reading mode RMD2, the reading part 70 can perform the first conversion gain reading operation HCGSRD of reading, in a first reading period PRD1 following a first transfer period PT1 after the reset reading period PRRD, from the output buffer part, the first read-out signal HCGVSIG resulting from conversion performed with the first conversion gain corresponding to the first amount of charges in the output node and performing a comparing operation at the comparator on the first read-out signal HCGVSIG. Furthermore, in the second reading mode RMD2, the reading part 70 uses the gain switching part to switch the gain after the first reading period PRD1 and can perform the second conversion gain reading operation LCGSRD of reading, in a second reading period PRD2 following a second transfer period PT2 after the first reading period PRD1, from the output buffer part, the second read-out signal LCGVSIG resulting from conversion performed with the second conversion gain corresponding to the second amount of charges in the output node and performing a comparing operation at the comparator on the second read-out signal LCGVSIG.

In the third reading mode RMD3, the reading part 70 can perform the first conversion gain reset reading operation HCGRRD of reading, in a first reset reading period PRRD1 following a first reset period PR1, from the output buffer part, the first read-out reset signal HCGVRST resulting from conversion performed with the first conversion gain corresponding to the first amount of charges in the output node and performing a comparing operation at the comparator on the first read-out reset signal HCGVRST. Furthermore, in the third reading mode RMD3, the reading part 70 can perform the first conversion gain reading operation HCGSRD of reading, in the first reading period PRD1 following the first transfer period PT1 after the first reset reading period PRRD1, from the output buffer part, the first read-out signal HCGVSIG resulting from conversion performed with the first conversion gain corresponding to the first amount of charges in the output node and performing a comparing operation at the comparator on the first read-out signal HCGVSIG. Furthermore, in the third reading mode RMD3, the reading part 70 uses the gain switching part to switch the gain after the first reading period PRD1 and can perform the second conversion gain reading operation LCGSRD of reading, in the second reading period PRD2 following the second transfer period PT2 after the first reading period PRD1, from the output buffer part, a second read-out signal LCGVSIG resulting from conversion performed with the second conversion gain corresponding to the second amount of charges in the output node and performing a comparing operation at the comparator on the second read-out signal LCGVSIG. In the third reading mode RMD3, the reading part 70 can perform the second conversion gain reset reading operation LCGRSD of reading, in the second reset reading period PRRD2 following the second reset period PR2 after the second reading period PRD2, from the output buffer part, a second read-out reset signal LCGVRST resulting from conversion performed with the second conversion gain corresponding to the second amount of charges in the output node and performing a comparing operation at the comparator on the second read-out reset signal LCGVRST.

In the fourth reading mode RMD4, the reading part 70 uses the clock to count the time required, when irregular and strong light enters the photoelectric conversion elements, to allow the overflow charges to change the potential at the output node (the floating diffusion FD) and to eventually invert the output from the comparator, so that the reading part 70 can predict the amount of the signal. The reading part 70 can perform the first conversion gain reset reading operation HCGRRD of reading, in the first reset reading period PRRD1, from the output buffer part, a first read-out reset signal HCGVRST resulting from conversion performed with the first conversion gain corresponding to the first amount of charges in the output node and performing a comparing operation at the comparator on the first read-out reset signal HCGVRST. Furthermore, in the fourth reading mode RMD4, the reading part 70 can perform the first conversion gain reading operation HCGSRD of reading, in a first reading period PRD1 following a first transfer period PT1 after the first reset reading period PRRD1, from the output buffer part, the first read-out signal HCGVSIG resulting from conversion performed with the first conversion gain corresponding to the first amount of charges in the output node and performing a comparing operation at the comparator on the first read-out signal HCGVSIG. Furthermore, in the fourth reading mode RMD4, the reading part 70 uses the gain switching part to switch the gain after the first reading period PRD1 and can perform the second conversion gain reading operation LCGSRD of reading, in a second reading period PRD2 following a second transfer period PT2 after the first reading period PRD1, from the output buffer part, the second read-out signal LCGVSIG resulting from conversion performed with the second conversion gain corresponding to the second amount of charges in the output node and performing a comparing operation at the comparator on the second read-out signal LCGVSIG. Furthermore, in the fourth reading mode RMD4, the reading part 70 can perform the second conversion gain reset reading operation LCGRSD of reading, in a second reset reading period PRRD2 following a second reset period PR2 after the second reading period PRD2, from the output buffer part, the second read-out reset signal LCGVRST resulting from conversion performed with the second conversion gain corresponding to the second amount of charges in the output node and performing a comparing operation at the comparator on the second read-out reset signal LCGVRST.

The following outlines the configurations and functions of the parts of the solid-state imaging device 10A. In particular, the configurations and functions of the pixel part 20A and pixels and the relating read-out operation will be described in detail, and other features will be also described in detail.

### <Example Configuration of Sharing Pixel 200A>

FIG. 7 shows an example of the circuit of the sharing pixel of the solid-state imaging device 10A relating to the second embodiment of the present invention.

As described above, the sharing pixels 200A relating to the second embodiment each include the photoelectric conversion reading part 210A, AD converting part 220, and memory part 230. The pixel part 20A relating to the second embodiment is configured as a stacked CMOS image sensor made up by the first and second substrates 110 and 120. In the present example, as shown in FIG. 7, the photoelectric conversion reading part 210A is formed in the first substrate 110, and the AD converting part 220 and the memory part 230 are formed in the second substrate 120.

The photoelectric conversion reading part 210A of the sharing pixel 200A includes two photodiodes (photoelectric conversion elements) and one in-pixel amplifier. More specifically, the photoelectric conversion reading part 210A includes, for example, a first photodiode PD1, which is a first photoelectric conversion element and a second photodiode PD1, which is a second photoelectric conversion element. In the sharing pixel 200A relating to the second embodiment, the first and second photodiodes PD0 and PD1 share the floating diffusion FD, which serves as an output node ND0.

The first and second photodiodes PD0 and PD1 perform photoelectric conversion to generate charges and store the generated charges in an integration period, first transfer transistor TG0-Tr, which serves as a first transfer element, is connected between the storing part PND0 of the first photodiode PD0 and the floating diffusion FD, and a first shutter gate transistor SG0-Tr, which serves as a first charge overflow gate element, is connected between the storing part PND0 and a predetermined fixed potential VAAPIX. A second transfer transistor TG1-Tr, which serves as a second transfer element, is connected between the storing part PND1 of the second photodiode PD1 and the floating diffusion FD, and a second shutter gate transistor SG1-Tr, which serves as a second charge overflow gate element, is connected between the storing part PND1 and the predetermined fixed potential VAAPIX.

The photoelectric conversion reading part 210A includes, for the floating diffusion FD serving as the single output node ND0, one reset transistor RST-Tr serving as a reset element, one source follower transistor SF-Tr serving as a source follower element, one storage transistor BIN-Tr serving as a storing element, one storage capacitor CS serving as a storing capacitance element, and one reading node ND1. The photoelectric conversion reading part 210 can further include a selection transistor SEL-Tr serving as a selecting element.

In the second embodiment, the source follower transistor SF-Tr and the reading node ND1 together constitute an output buffer part 211. The storage transistor BIN-Tr and the storage capacitor CS together constitute a gain switching part 212.

In the photoelectric conversion reading part 210A relating to the second embodiment, the reading node ND1 of the output buffer part 211 is connected to the input part of the AD converting part 220. The photoelectric conversion reading part 210A converts the charges in the floating diffusion FD serving as an output node into a voltage signal at a level corresponding to the amount of the charges and outputs the voltage signal VSL to the AD converting part 220.

Under the control of the reading part 70, the photoelectric conversion reading part 210A relating to the second embodiment reads the charges stored in the first photodiode PD0 serving as the first photoelectric conversion element, in the fourth reading mode RMD4 or third reading mode RMD3. Following this, the photoelectric conversion reading part 210A reads the charges stored in the second photodiode PD1 serving as the second photoelectric conversion element, in the first reading mode RMD1 or second reading mode RMD2. In the second embodiment, the charges stored in the first photodiode PD0 serving as the first photoelectric conversion element are read out in the fourth reading mode RMD4, and the charges stored in the second photodiode PD1 serving as the second photoelectric conversion element are read out in the second reading mode RMD2.

For example, the photoelectric conversion reading part 210A outputs, in a first comparing operation period PCMP1 of the AD converting part 220, a voltage signal VSL corresponding to the overflow charges overflowing from the photodiode PD0, which is a photoelectric conversion element, to the floating diffusion FD serving as an output node in an integration period PI, as described above.

Furthermore, the photoelectric conversion reading part 210A outputs, in a second comparing operation period PCMP2 of the AD converting part 220, a voltage signal VSL corresponding to the charges stored in the photodiode PD1 that are transferred to the floating diffusion FD serving as an output node in a transfer period PT following the integration period PI. The photoelectric conversion reading part 210A outputs a read-out reset signal (signal voltage) (VRST) and a read-out signal (signal voltage) (VSIG), as a pixel signal, to the AD converting part 220 in the second comparing operation period PCMP2.

The first and second photodiodes PD0 and PD1 generate signal charges (electrons) in an amount determined by the amount of the incident light and stores the same. The photodiodes (PDs) in the sharing pixel 200A are pinned photodiodes (PPDs). The substrate surface for forming the photodiodes (PDs) has a surface level due to dangling bonds or other defects. Therefore, a lot of charges (dark current) are generated due to heat energy, as a result of which the signals fail to be read out correctly. The pinned photodiodes (PPDs) have the charge storage part buried in the substrate, thereby reducing mixing of the dark current into the signals.

The first transfer transistor TG0-Tr of the photoelectric conversion reading part 210A is connected between the storing part PND0 of the first photodiode PD0 and the floating diffusion FD and controlled by a control signal TG0 applied to the gate thereof through a control line. The first transfer transistor TG0-Tr remains selected and in the conduction state during a transfer period PT in which the control signal TG0 is at the high (H) level, to transfer to the floating diffusion FD the charges (electrons) produced by the photoelectric conversion and then stored in the first photodiode PD0. After the first photodiode PD0 and the floating diffusion FD are reset to a predetermined reset potential, the first transfer transistor TG0-Tr enters the non-conduction state with the control signal TG0 being set to the low (L) level and the first photodiode PD0 enters an integration period PI. Under these circumstances, if the intensity of the incident light is very high (the amount of the incident light is very large), the charges above the well capacity overflow into the floating diffusion FD as overflow charges through the overflow path under the first transfer transistor TG0-Tr.

The first shutter gate transistor SG0-Tr serving as the first charge overflow gate element is connected between the storing part PND0 of the first photodiode PD0 and the predetermined fixed potential VAAPIX and controlled by a control signal SG0 applied thereto through a control line. The first shutter gate transistor SG0-Tr remains selected and in the conduction state during the period in which the control signal SG0 is at the H level, to form a charge release (discharge) path providing for antiblooming function between the charge storing part PND0 of the first photodiode PD0 and the predetermined fixed potential VAAPIX. In this way, unnecessary charges are released to the fixed potential VAAPIX.

As described above, the first transfer transistor TG0-Tr and the first shutter gate transistor SG0-Tr are driven and controlled at individually selected timings.

The second transfer transistor TG1-Tr of the photoelectric conversion reading part 210A is connected between the storing part PND1 of the second photodiode PD1 and the floating diffusion FD and controlled by a control signal TG1 applied to the gate thereof through a control line. The second transfer transistor TG1-Tr remains selected and in the conduction state during a transfer period PT in which the control signal TG1 is at the high (H) level, to transfer to the floating diffusion FD the charges (electrons) produced by the photoelectric conversion and then stored in the second photodiode PD1. After the second photodiode PD1 and the floating diffusion FD are reset to a predetermined reset potential, the second transfer transistor TG1-Tr enters the non-conduction state with the control signal TG1 being set to the low (L) level and the second photodiode PD1 enters an integration period PI. Under these circumstances, if the intensity of the incident light is very high (the amount of the incident light is very large), the charges above the well capacity overflow into the fixed potential VAAPIX as overflow charges through the overflow path under the second shutter gate transistor SG1-Tr.

The second shutter gate transistor SG1-Tr serving as the second charge overflow gate element is connected between the storing part PND1 of the second photodiode PD1 and the predetermined fixed potential VAAPIX and controlled by a control signal SG1 applied thereto through a control line. The second shutter gate transistor SG1-Tr remains selected and in the conduction state during the period in which the control signal SG1 is at the H level, to form a charge release (discharge) path providing for antiblooming function between the charge storing part PND1 of the second photodiode PD1 and the predetermined fixed potential VAAPIX. In this way, unnecessary charges are released to the fixed potential VAAPIX.

As described above, the second transfer transistor TG1-Tr and the second shutter gate transistor SG1-Tr are driven and controlled at individually selected timings.

The reset transistor RST-Tr is connected between the power supply line Vaapix of the power supply voltage VAAPIX and the floating diffusion FD and controlled by a control signal RST applied to the gate thereof through a control line. The reset transistor RST-Tr remains selected and in the conduction state during a reset period in which the control signal RST is at the H level, to reset the floating diffusion FD to the potential (Vrst) of the power supply line Vaapix of the power supply voltage VAAPIX.

The storage transistor BIN-Tr is connected between the floating diffusion FD and the reset transistor RST-Tr, and the storage capacitor CS is connected between a connection node ND2, which is located between the storage transistor BIN-Tr and the reset transistor RST-Tr, and the reference potential VSS. The storage transistor BIN-Tr is controlled by a control signal BIN applied to the gate thereof through a control line. The storage transistor BIN-Tr remains selected and in the conduction state during a reset period in which the control signal BIN is at the H level so as to connect the floating diffusion FD and the storage capacitor CS.

The first conversion gain signal reading operation HCGSRD is performed while the storage transistor BIN-Tr remains in the non-conduction state, so that the charges in the floating diffusion FD serving as the output node ND0 are separated from the charges in the storage capacitor CS. The second conversion gain signal reading operation LCGSRD is performed while the storage transistor BIN-Tr remains in the conduction state, so that the charges of the floating diffusion FD serving as the output node ND0 are combined with the charges in the storage capacitor CS. The second conversion gain reset reading operation LCGRRD is performed while the reset transistor RST-Tr and the storage transistor BIN-Tr remain in the conduction state, so that the charges of the floating diffusion FD serving as the output node ND0 and the charges of the storage capacitor CS are cleared.

The source follower transistor SF-Tr serving as a source follower element is connected at the source thereof to the reading node ND1, at the drain thereof to the power supply line Vaapix, and at the gate thereof to the floating diffusion FD. The output node ND1 forming the output buffer part 211 is connected to a signal line LSGN1, which is connected to the input part of the AD converting part 220. The drain and source of the current transistor IC-Tr serving as a current source element are connected between (i) the signal line LSGN1 to which the reading node ND1 is connected and (ii) the reference potential VSS (for example, GND). The gate of the current transistor IC-Tr is connected to the feeding line of a control signal VBNPIX. The signal line LSGN1 between the reading node ND1 and the input part of the AD converting part 220 is driven by the current transistor IC-Tr serving as a current source element.

Under the first transfer transistor TG0-Tr, an overflow path OVP is formed extending from the first photodiode PD0 to the floating diffusion FD. The potential of the overflow path OVP can also be controlled through gate control, for example.

A gate electrode 2110 of the second transfer transistor TG1-Tr and a gate electrode 2111 of the second shutter gate transistor SG1-Tr are formed. Under the second shutter gate transistor SG1-Tr, a charge release path DMP is formed extending from the second photodiode PD1 to the VAAPIX node.

With the above-described structure, if the intensity of the incident light is very high (the amount of the incident light is very large), the charges above the well capacity overflow into the floating diffusion FD as overflow charges through the overflow path OVP under the first transfer transistor TG0-Tr. The overflow charges are used in the first comparing operation CMPR1 performed by the comparator 221.

On the other hand, if irregular and strong light enters the first photodiode PD0 during the second comparing operation of the AD conversion, the charges overflow from the photodiode PD0 to the floating diffusion FD and the level of the floating diffusion FD serving as the output node changes. As a consequence, the AD conversion may possibly fail to be completed successfully. To address this issue, the present embodiment employs the first shutter gate transistor SG0-Tr. In this way, if irregular and strong light enters the first photodiode PD0 during the second comparing operation, unnecessary charges may be released from the first photodiode PD0 to a region where the floating diffusion FD is not formed. The first shutter gate transistor SG0-Tr thus prevents a change in the level of the floating diffusion, which may be caused by the charges overflowing from the first photodiode PD0 to the floating diffusion FD. In this way, even if irregular and strong light enters the first photodiode PD0 during the second comparing operation, the pixel is configured to be capable of successfully completing AD conversion by preventing a change in the FD level.

In the photoelectric conversion reading part 210A of the pixel 200A in which the single floating diffusion FD serving as the output node ND0 is shared between the set of the first photodiode PD0, the first transfer gate transistor TG0-Tr and the first shutter gate transistor SG0-Tr and the set of the second photodiode PD1, the second transfer gate transistor TG1-Tr and the second shutter gate transistor SG1-Tr, the capacity of the photodiodes PD is adapted to accommodate different reading modes for the purpose of improving the dynamic range. According to the second embodiment, since the charges stored in the first photodiode PD0 are read out using the fourth reading mode RMD4 and the charges stored in the second photodiode PD1 are read out using the second reading mode RMD2, the first and second photodiodes PD0 and PD1 adjacent to each other in the photoelectric conversion reading part 210A is configured such that the capacity of the former is smaller than the capacity of the latter.

The full well capacity (FWC) of the first photodiode PD0, which is read using the fourth reading mode RMD4, is limited by the FD saturation, not by its own FWC. On the other hand, the FWC of the second photodiode PD1, which is read using the first reading mode RMD1 or other reading modes, is limited by its own FWC. Accordingly, while the first photodiode PD0, which is read using the fourth reading mode RMD4, is configured to have a small FWC, the second photodiode PD1, which is read using the first reading mode RMD1 or other reading modes, is configured to have a large FWC.

### (PD0):

In the pixel 200A, the charges integrated in the first photodiode PD0 (MQPD) are stored in the PD node PND0, and the overflowing charges from the first photodiode PD0 are stored in the FD node. Therefore, the saturation signal is limited not by the FWC of the PD but by the FD saturation. Accordingly, the first photodiode PD0 (MQPD) is configured to have a small FWC, and the second photodiode PD1 (SQPD) is configured to have a large FWC. The photo charges can be read at least twice with different gains to be entirely converted into signals.

### (PD1):

The charges integrated in the second photodiode PD1 (SQPD) are stored in the PD node PND1, and the overflowing charges from the second photodiode PD1 are discharged to the drain node through the charge release path DMP. Therefore, the saturation signal is limited not by the FWC of the FD but by the PD saturation. Accordingly, the MQPD is configured to have a small FWC, and the SQPD is configured to have a large FWC.

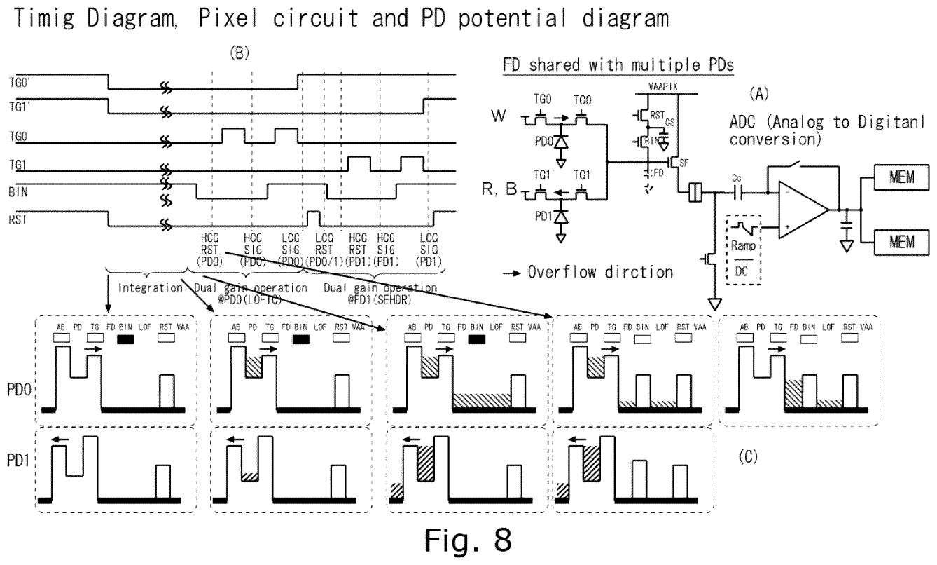

FIG. 8 includes views (A), (B) and (C) showing an example of a read-out operation applicable to the sharing pixel of the solid-state imaging device relating to the second embodiment of the present disclosure, namely, an example of the circuitry of the sharing pixel, a timing chart and potential transition in relation with each other.

According to the example shown, upon elapse of a charge integration period, a dual conversion gain operation using LOFIC is firstly performed to read the charges in the first photodiode PD0. Specifically, a high conversion gain reset signal read-out operation HCGRST(PD0), a high conversion gain illuminance signal read-out operation HCGSIG(PD0), and a low conversion gain illuminance signal read-out operation LCGSIG(PD0) are performed in order on the first photodiode PD0.

After this, a dual conversion gain operation using SEHDR is next performed to read the charges in the second photodiode PD1. Specifically, a low conversion gain reset signal read-out operation LCGRST(PD0/1) is performed on the first or second photodiode PD0 or PD1. After this, a high conversion gain reset signal read-out operation HCGRST(PD1), a high conversion gain illuminance signal read-out operation HCGSIG(PD1), and a low conversion gain illuminance signal read-out operation LCGSIG(PD1) are performed in order.

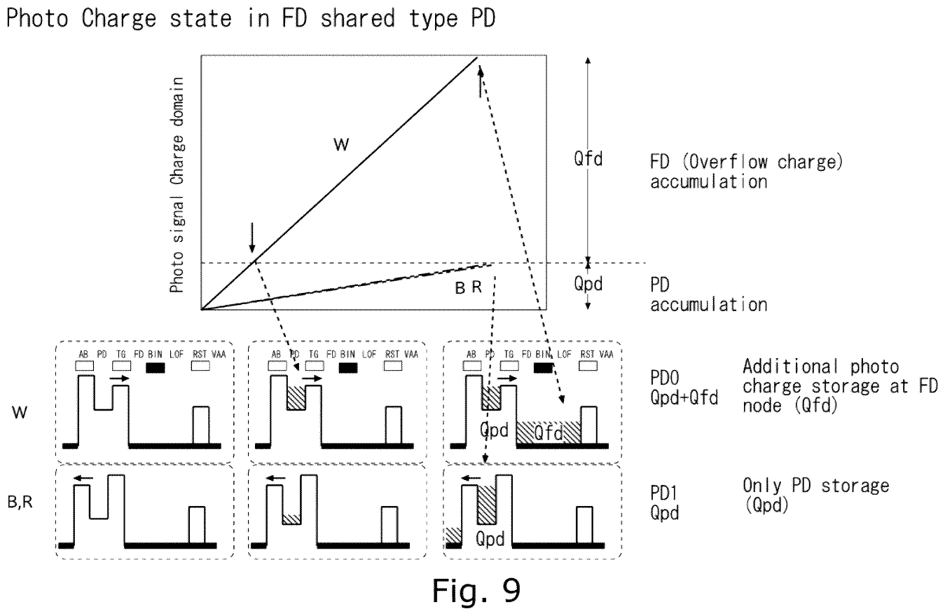

The following now describes a photo charge state in a FD-shared PD. FIG. 9 describes a photo charge state in a FD-shared PD in relation to potential transition.

According to this example, the responsiveness of the “W” pixel [e⁻/lux] is estimated four times higher, and the charges (Qfd) stored in the floating diffusion FD (FD node) are also estimated to be four times greater. The saturation point [lux] of the high-transmission W filter is extended, so that the saturation points are leveled. In this example, the overflow charges from the clear (white) filter can be stored in the floating diffusion FD (FD node). The overflow charges from the R/B filters are not coupled with the FD node during exposure, and the R and G filters are coupled with the FD node only during a read-out period.

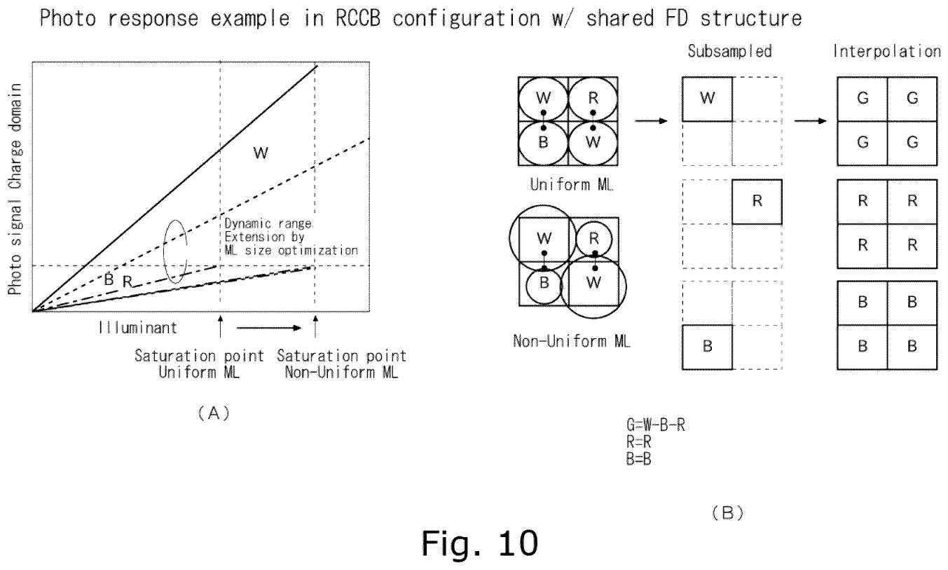

The following now describes an example of photo response in a RWWB (RCCB) configuration with a shared FD structure and color matrix interpolation. FIG. 10 includes views (A) and (B) to illustrate an example of photo response in a RWWB (RCCB) configuration with a shared FD structure and color matrix interpolation. In FIG. 10, the view (A) shows an example of photo response characteristics, and the view (B) shows an example of color matrix interpolation in a RWWB (RCCB) color matrix. The views (A) and (B) in FIG. 10 show transmittance of regular color filters and a G filter.

According to the configuration shown in FIG. 10, the dynamic range of W can be extended by optimization of the microlenses ML, as is seen from the view (A). As for the color matrix interpolation shown in the view (B) in FIG. 10, the W (C), B and R filters are used to perform an operation G=W−B−R, so that the green G filter performance can be reproduced at a level close to the original G filter performance.

The following further describes how to read pixel signals in the second embodiment. A reading method applicable to the sharing pixel can be typified by methods applicable to first, second and third cases.

The first case is applied to read pixel signals from all pixels or perform binning. A single gain is used as the read-out gain, which is selected from among the high conversion gain (first conversion gain) HCG and the low conversion gain (second conversion gain) LCG. In this case, a reading operation is performed on either the first or second photodiode PD0 or PD1.

The second case is applied to single exposure high dynamic range (SEHDR) performance. A dual conversion gain scheme is used, specifically, the high conversion gain (first conversion gain) HCG and the low conversion gain (second conversion gain) LCG are both used. In this case, the charges in the first photodiode PD0 are firstly read with the high conversion gain HCG, and the charges in the second photodiode PD1 are secondly read with the low conversion gain LCG.

The third case is applied to the LOFIC mode. A dual conversion gain scheme is used, specifically, the high conversion gain (first conversion gain) HCG and the low conversion gain (second conversion gain) LCG are both used. In this case, the charges in the first photodiode PD0 are firstly read with the high conversion gain HCG, and the charges in the floating diffusion FD are secondly read with the low conversion gain LCG.

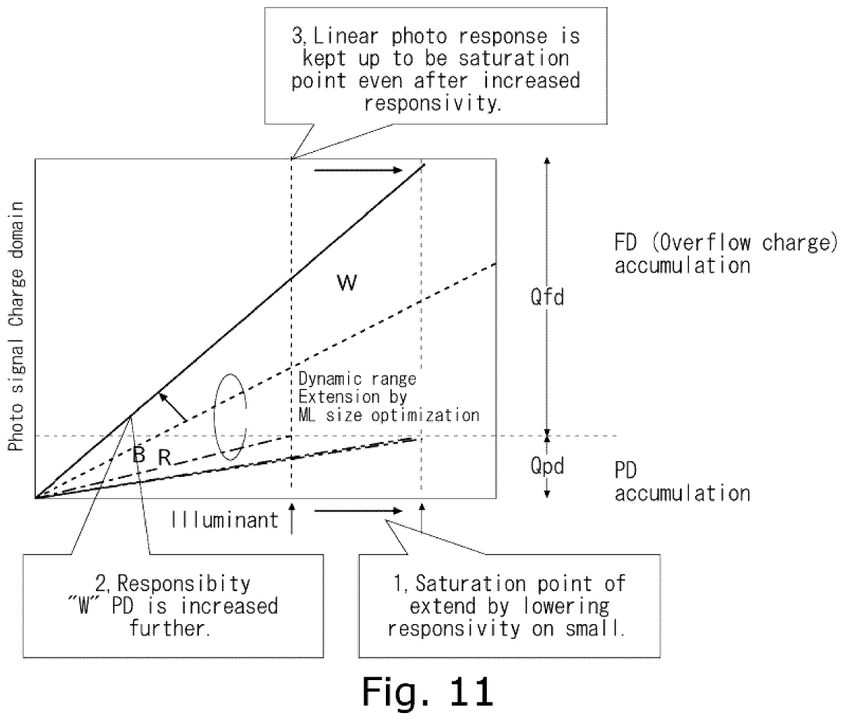

The above has described the characteristic configurations and functions of the solid-state imaging device 10A relating to the second embodiment including sharing pixels, where each sharing pixel has two photodiodes PD0 and PD1 and one floating diffusion FD is shared between the photodiodes PD0 and PD1. The following now describes the advantageous effects of the solid-state imaging device 10A relating to the second embodiment, with reference to FIG. 11. In FIG. 11, the reference numeral 1 indicates the saturation point, which is extended by lowering the responsivity on small ML (on large ML), the reference numeral 2 indicates the responsivity of the “W” PD may further increase, and the reference numeral 3 indicates that the linear photo response can be maintained until the saturation point is reached even if the sensitivity is increased.

### Advantageous Effects of Second Embodiment

According to the above-described configuration, the saturation point of the underlying transparent (R-B) color matrix is limited by the characteristics of the W filter. The saturation point of the RB (W) filter configuration, where the W (clear) filter is provided to achieve higher transparency, is limited by the W filter. Therefore, the maximum illuminance, which normally contributes to achieve color reproducibility, may drop. If overflow charges are stored in the FD in the FD-sharing PDs, the PD having the highest transmittance can achieve increased full well capacity.

The second embodiment can achieve higher responsiveness and also accomplish higher SNR performance in low illuminance environment while an increased dynamic range can be obtained as well as excellent color reproducibility. In addition, the second embodiment can allow some of the pixel circuit components such as the FD and gain buffer to be shared among a plurality of PDs and achieve improved saturation when compared with the conventional dual-size PD and LOFIC configurations, thereby realizing a smaller pixel size and higher resolution.

### Third Embodiment

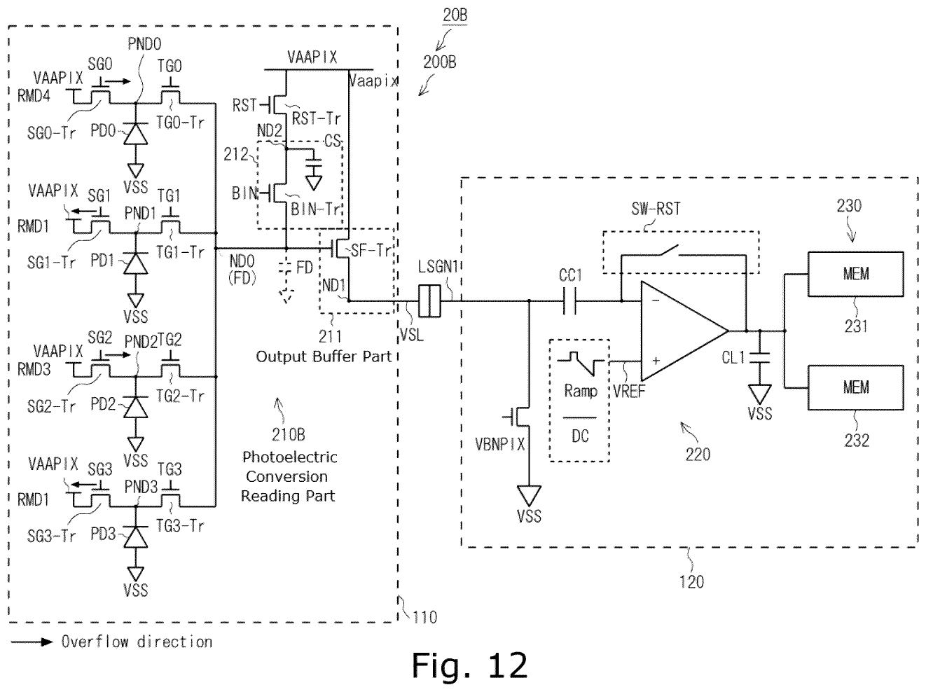

FIG. 12 is a circuit diagram showing an example of a sharing pixel of a solid-state imaging device relating to a third embodiment of the present invention.

A sharing pixel 200B of the solid-state imaging device 10B relating to the third embodiment differs from the sharing pixel 200A of the solid-state imaging device 10A relating to the above-described second embodiment in the following points.

In the sharing pixel 200A of the solid-state imaging device 10A relating to the second embodiment, the two photodiodes PD0 and PD1 share one floating diffusion FD. Specifically, the solid-state imaging device 10A relating to the second embodiment includes the first photodiode PD0 connected to the first transfer transistor TG0-Tr, the second photodiode PD1 connected to the second transfer transistor TG1-Tr, the floating diffusion FD connected to the first and second transfer transistors TG0-Tr and TG1-Tr, the first shutter gate transistor SG0-Tr serving as an anti-blooming gate connected to the first photodiode PD0, and the second shutter gate transistor SG1-Tr serving as an anti-blooming gate connected to the second photodiode PD1. In the sharing pixel 200A of the solid-state imaging device 10A relating to the second embodiment, the first saturation signal SAT0 from the first photodiode PD0 entirely overflows into the floating diffusion FD via the first transfer transistor TG0-Tr, and the second saturation signal SAT1 from the second photodiode PD1 is discharged through the second shutter gate transistor SG1-Tr.

In the sharing pixel 200B of the solid-state imaging device 10B relating to the third embodiment, four photodiodes PD0 to PD3, namely, the two photodiodes PD0 and PD1 and additional two photodiodes PD2 and PD3, share one floating diffusion FD. Specifically, the solid-state imaging device 10B relating to the third embodiment includes a first photodiode PD0 connected to a first transfer transistor TG0-Tr, a second photodiode PD1 connected to a second transfer transistor TG1-Tr, a third photodiode PD2 connected to a third transfer transistor TG2-Tr, a fourth photodiode PD3 connected to a fourth transfer transistor TG3-Tr, a floating diffusion FD connected to the first, second, third and fourth transfer transistors TG0-Tr, TG1-Tr, TG2-Tr and TG3-Tr, a first shutter gate transistor SG0-Tr serving as an anti-blooming gate connected to the first photodiode PD0, a second shutter gate transistor SG1-Tr serving as an anti-blooming gate connected to the second photodiode PD1, a third shutter gate transistor SG2-Tr serving as an anti-blooming gate connected to the third photodiode PD2, and a fourth shutter gate transistor SG3-Tr serving as an anti-blooming gate connected to the fourth photodiode PD3.

As noted above, the sharing pixel 200B of the solid-state imaging device 10B relating to the third embodiment additionally includes the third and fourth photodiodes PD2 and PD3 respectively coupled with the third and fourth transfer transistors TG2-Tr and TG3-Tr. The layout of the FD shared pixel 200B is as follows. The first, second, third and fourth photodiodes PD0, PD1, PD2 and PD3 are provided, and all of the saturation signals SAT0 to SAT3 from the photodiodes PD0 to PD3 are completely transferred (overflow) to the floating diffusion FD, and theirs own overflow charges can be discharged to the drain via the other side of the transfer transistors TG (shutter gate transistors SG). Alternatively or additionally, at least one of the saturation signals SAT0 to SAT3 from the photodiodes PD0 to PD3 is completely transferred (overflows) to the floating diffusion FD, but their own overflow charges can be discharged to the drain via the other side of the transfer transistors TG (shutter gate transistors SG).

In the sharing pixel 200B, the photodiodes PD0 to PD3 are each connected to two charge transfer transistors through which the stored charges can be discharged to independently control the duration of integration. The sharing pixel 200B has color filters formed above the corresponding PDs sharing the FD. For example, a color filter configuration of RGB, G filters is applied to a 2×2 block of PDs sharing an FD. Due to the FD shared configuration, the pixels can be formed above a back sided isolation (BSI) structure using a partial full DTI, which can prevent color signal cross talk between the photodiodes PD0 to PD3.

The sharing pixel 200B includes color filters arranged correspondingly to the pixels respectively including the photoelectric conversion elements. A high-sensitivity and high-transmittance color filter W (C) is applied to a first one of the photoelectric conversion elements from which the overflow photo charges are stored into the floating diffusion FD. Relatively less sensitive transmissive color filters are applied to second and subsequent photoelectric conversion elements in which the produced photo charges are accumulated as a read-out signal. In order to extend the overflow signal from the high-sensitivity pixel, the color filters of the other pixels than the high-sensitivity pixel are configured as R-G-B-IR, or combined with a filter sensitive to any one of the relatively less transmissive color filters.

The solid-state imaging device 10B relating to the third embodiment can be configured in the same manner as the solid-state imaging devices 10 and 10A relating to the above-described first and second embodiments. Specifically, as in the first and second embodiments, large-sized microlenses MLL are allocated to color filters having high transparency (transmittance), for example, (W) filters, and small-sized microlenses MLS are allocated to color filters having low transparency, for example, visible light filters (B, R) in the third embodiment. The microlenses ML are non-uniform. The color filters underlying the large-sized microlenses MLL need to be made from a highly transparent material.

The following now describes in order the configurations and layout of the sharing pixels of the solid-state imaging device 10B relating to the third embodiment, the configuration and function of the color matrix.

### <Example of 2×2 Color Matrix>

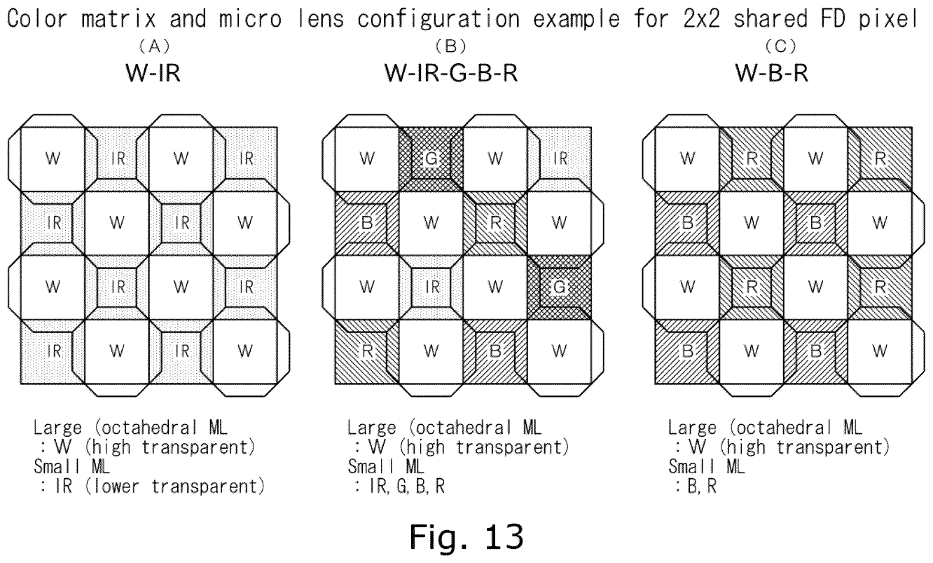

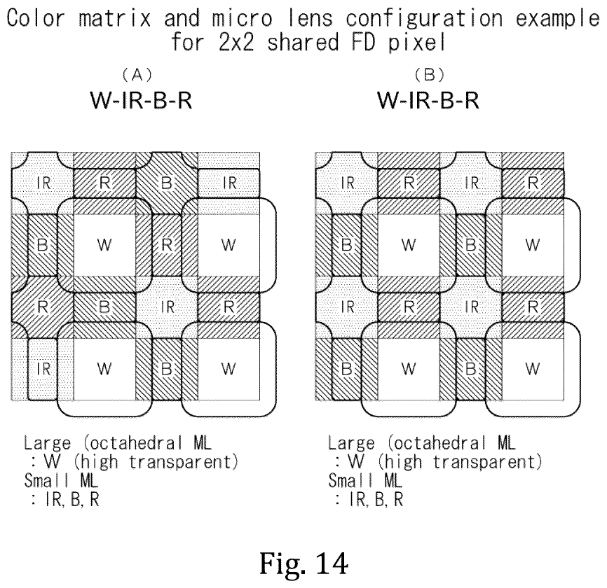

The following now describes an example of a 2×2 color matrix. The views (A) to (C) in FIG. 13 show examples of a color matrix for 2×2 FD-shared pixels, so do the views (A) and (B) in FIG. 14.

In FIG. 13, the view (A) shows an example of a color matrix where W-IR pixels are arranged in a 2×2 square pattern, the view (B) shows an example of a color matrix where W-IR-G-B-R pixels are arranged in a 2×2 square pattern, the view (C) shows an example of a color matrix where W-B-R pixels are arranged in a 2×2 square pattern. In FIG. 14, the views (A) and (B) show examples of a color matrix where W-IR-B-R pixels are arranged in a 2×2 square pattern.

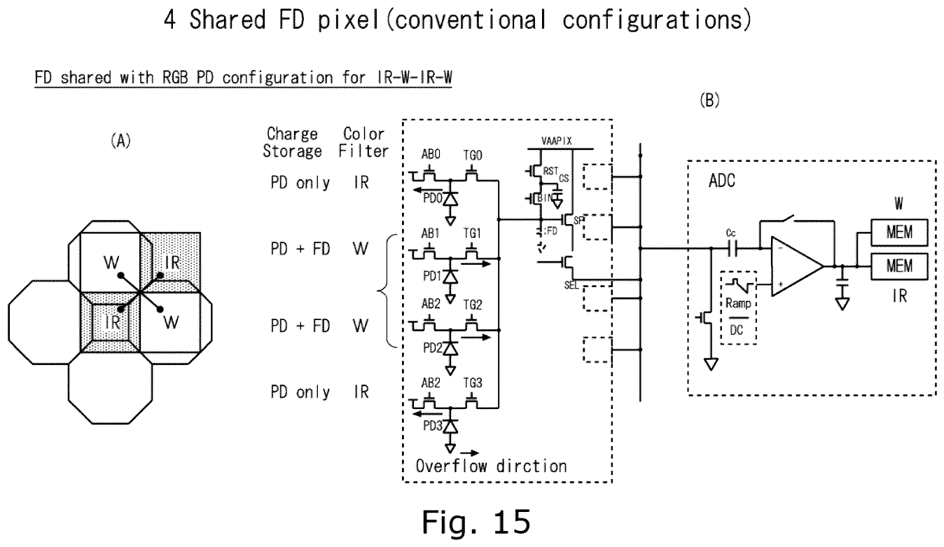

FIG. 15 includes views (A) and (B) showing an example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel. Referring to the example, a first photodiode PD0 has a color filter IR allocated and is configured to store the produced charges only in the PD. A second photodiode PD1 has a color filter W allocated and is configured to store the produced charges in the PD and FD. A third photodiode PD2 has a color filter W allocated, and is configured to store the produced charges in the PD and FD. A fourth photodiode PD3 has a color filter IR allocated and is configured to store the produced charges only in the PD.

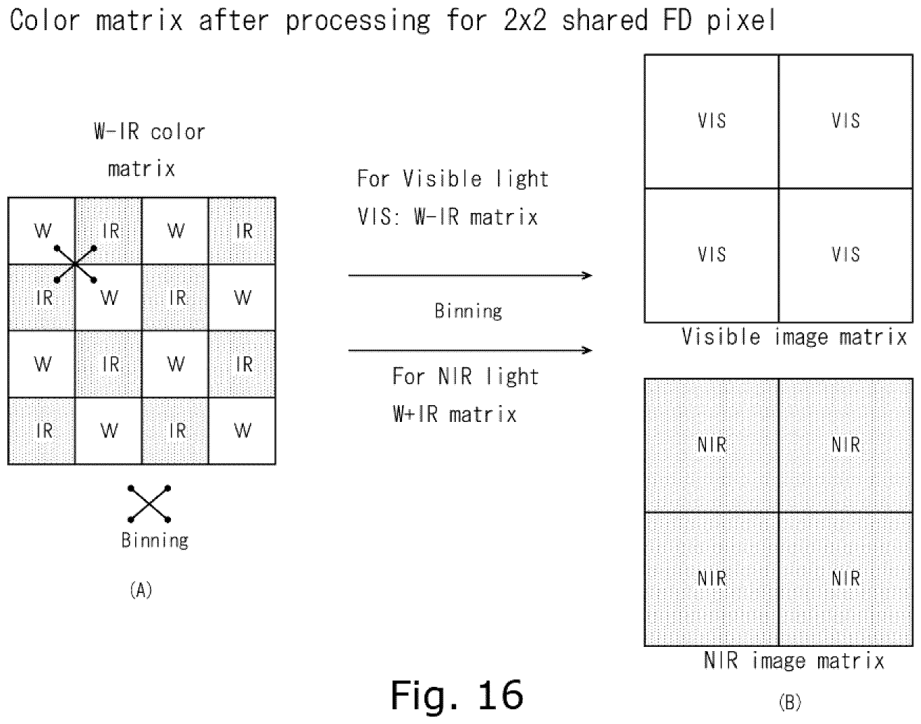

FIG. 16 includes views (A) and (B) showing an example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel. A visible image matrix can be achieved by performing binning on visible light VIS: W-IR color matrix for reading of the visible light VIS. An NIR image matrix can be achieved by performing binning on NIR light W-IR color matrix for reading of the NIR light W-IR.

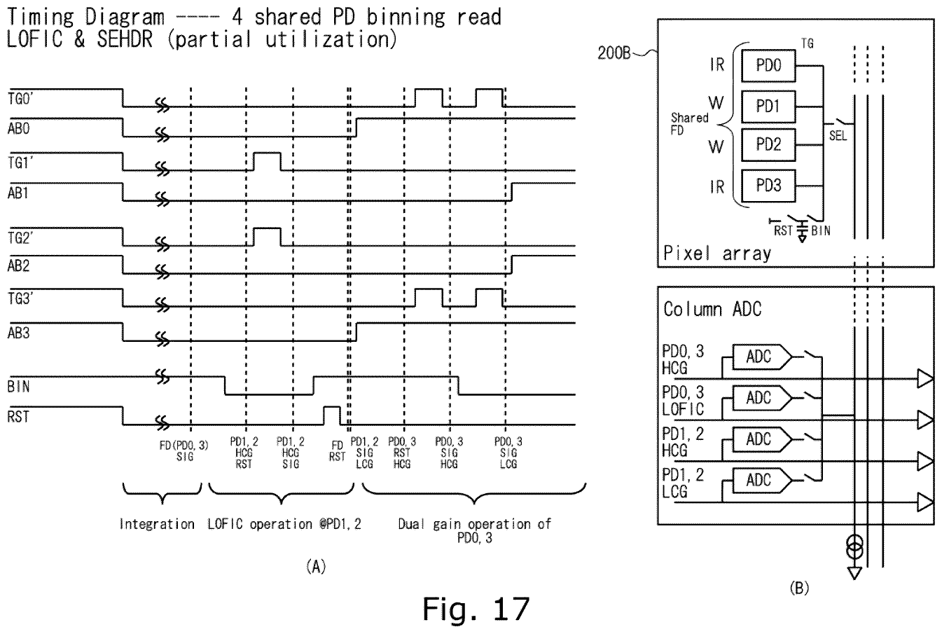

FIG. 17 includes a timing chart (A) illustrating an example of a four shared PD binning read-out operation with LOFIC and SEHDR being partially utilized applicable to the sharing pixel of the solid-state imaging device relating to the third embodiment of the present disclosure, along with a view (B) showing an example of the reading circuit of the sharing pixel.

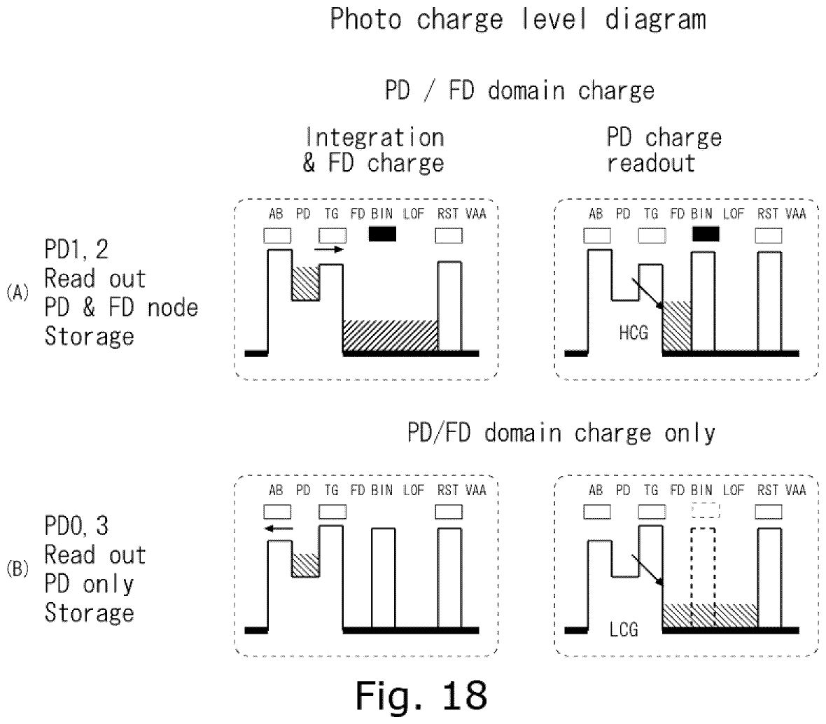

FIG. 18 includes views (A) and (B) showing an example of a read-out operation with LOFIC being partially utilized and SEHDR applicable to the solid-state imaging device relating to the third embodiment of the present disclosure.

A reading method with LOFIC and SEHDR being partially used applicable to the sharing pixel can be typified by the method applicable to the cases shown in the views (A) and (B) in FIG. 18.

In FIG. 18, the view (A) shows an example of how to read the charges in the photodiodes PD0 and PD3 with the high conversion gain, and the view (B) shows an example of how to read the charges in the photodiodes PD1 and PD2 with the low conversion gain.

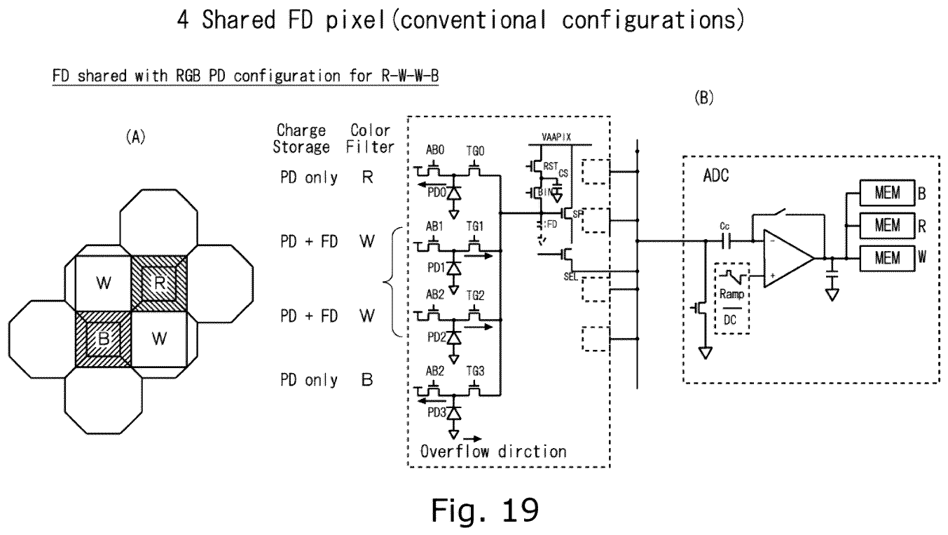

FIG. 19 includes views (A) and (B) showing another example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel. Referring to the example, a first photodiode PD0 has a color filter R allocated and is configured to store the produced charges only in the PD. A second photodiode PD1 has a color filter W allocated and is configured to store the produced charges in the PD and FD. A third photodiode PD2 has a color filter W allocated, and is configured to store the produced charges in the PD and FD. A fourth photodiode PD3 has a color filter B allocated and is configured to store the produced charges only in the PD.

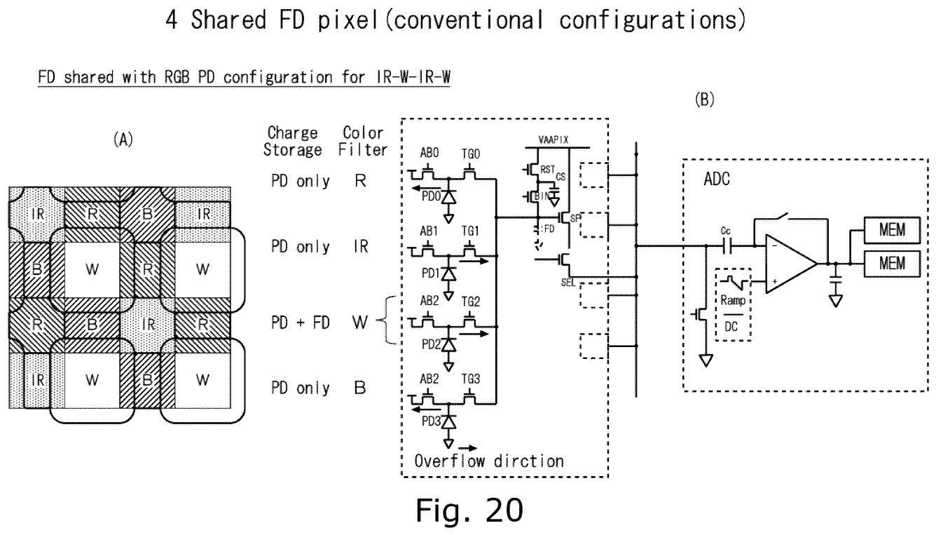

FIG. 20 includes views (A) and (B) showing another example of a color matrix for a 4-FD-sharing pixel of IR-W-IR-W RGB-PD configuration, where the PDs are arranged in a 2×2 square pattern with the shared FD being arranged in the center, in relation with an example of the reading circuitry for the sharing pixel. Referring to the example, a first photodiode PD0 has a color filter R allocated and is configured to store the produced charges only in the PD. A second photodiode PD1 has a color filter IR allocated and is configured to store the produced charges only in the PD. A third photodiode PD2 has a color filter W allocated, and is configured to store the produced charges in the PD and FD. A fourth photodiode PD3 has a color filter B allocated and is configured to store the produced charges only in the PD.

The following now briefly describes the characteristic configurations and functions of the solid-state imaging device 10B relating to the third embodiment including sharing pixels, where each sharing pixel has four photodiodes PD0, PD1, PD2 and PD3 and one floating diffusion FD shared between the photodiodes PD0, PD1, PD2 and PD3.

As described above, the FD sharing pixel of the third embodiment is constituted by the first to fourth photodiodes PD0 to PD3, and at least one of the PD saturation signals is completely transferred (overflow) to the floating diffusion FD. On the other hand, their own overflow charges can be discharged through the other side of the TG (AB). The pixel is constituted by the PDs sharing the FD and the other components described in the first and second embodiments. The photodiodes PDs each have a dump drain and a control gate, so that the stored charges can be discharged to independently control the duration of integration. The color filters are formed above the corresponding PDs sharing the FD. For example, a group of color filters at least one of which is a W filter is applied to one 2×2 block of PDs sharing an FD.

This enables the binning function of the PDs sharing a FD. In addition, the overflow charges can be stored in the FD node, which is further fully increased due to the 2×2 binning. The sequence of operations to read the pixel signal can be initiated by reading an initial PD read-out (Qpd0) signal, followed by an overflow signal (Qfd). After this, as the second step, a PD signal (Qpdq) is read out. Thus, the total amount of photo charges is Qpd+Qfd for the first PD and Qfd for the second PD. Therefore, the full well capacity of the first PD0 in the FD-sharing PDs can be increased. The microlenses (ML) of the respective pixels can be applied to the respective PDs, so that large-sized ML are arranged for the high-transparency filters and allocated to high-saturation PDs.

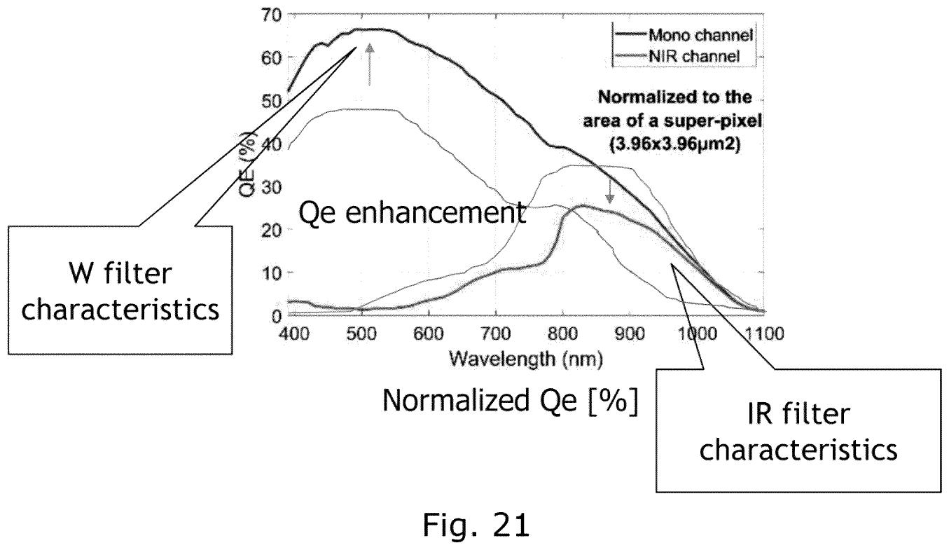

The following now describes the advantageous effects of the solid-state imaging device 10B relating to the third embodiment, with reference to FIG. 21.

### Advantageous Effects of Third Embodiment

In the third embodiment, the saturation signals of the FD-sharing PDs can be extended if overflow charges are stored in the PDs. As described above, higher responsiveness can be assigned to the FD-extended PDs, so that improved SNR performance in low-illuminance environment and enhanced dynamic range can be both achieved. The IR channel basically operates in a (single) quantization mode. Given the low DR requirement, the charge overflow path of the IR channel is designed to pass through the anti-blooming gate (AB). The anti-blooming gate (AB) is designed to prevent mixing of overflow charges from the FD mono-channel. For each photodiode (PD), its own transfer gate (TG) and AB gate signals are driven, so that the exposure time can be independently controlled. Therefore, the exposure time may be different between two channels and the ambient light and NIR projectors respectively emit light, Accordingly, the exposure time can be optimized.

As described above, the solid-state imaging device relating to the third embodiment can achieve higher SNR performance in low illuminance environment and better responsiveness, which can contribute to accomplishing higher dynamic range without overhead for the pixel size, than does solid-state imaging devices employing the conventional binning scheme.

The solid-state imaging devices 10, 10A, 10B described above can be applied, as an imaging device, to electronic apparatuses such as digital cameras, video cameras, mobile terminals, surveillance cameras, and medical endoscope cameras.

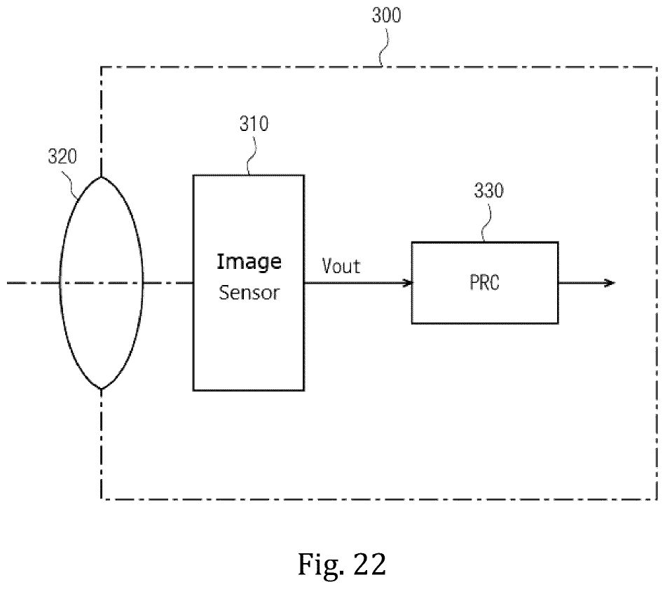

FIG. 22 shows an example of the configuration of an electronic apparatus including a camera system to which the solid-state imaging devices relating to the embodiments of the present disclosure are applied.

As shown in FIG. 22, the electronic apparatus 300 includes a CMOS image sensor 310 that can be constituted by any of the solid-state imaging devices 10, 10A and 10B relating to the embodiments of the present disclosure. The electronic apparatus 300 further includes an optical system (such as a lens) 320 for redirecting the incident light to the pixel region of the CMOS image sensor 310 (to form a subject image). The electronic apparatus 300 includes a signal processing circuit (PRC) 330 for processing the output signals from the CMOS image sensor 310.

The signal processing circuit 330 performs predetermined signal processing on the output signals from the CMOS image sensor 310. The image signals resulting from the processing in the signal processing circuit 330 can be handled in various manners. For example, the image signals can be displayed as a video image on a monitor having a liquid crystal display, printed by a printer, or recorded directly on a storage medium such as a memory card.

As described above, a high-performance, compact, and low-cost camera system can be provided that includes the solid-state imaging device 10, 10A, 10B as the CMOS image sensor 310. Accordingly, the embodiments of the present disclosure can provide for electronic apparatuses such as surveillance cameras and medical endoscope cameras, which are used for applications where the cameras are installed under restricted conditions from various perspectives such as the installation size, the number of connectable cables, the length of cables and the installation height.

What is claimed is:

1. A solid-state imaging device comprising
a pixel part having an array of pixels arranged therein, each of the pixels including a photoelectric conversion part and being configured to perform photoelectric conversion on light incident thereon,
wherein, in the pixel part, at least two adjacent pixels of the pixels form a pixel unit,
wherein a first pixel of the pixel unit includes:
a first transmission filter having a predetermined transparency, the first transmission filter being provided on a light incidence path leading to a light incidence surface of a corresponding photoelectric conversion part; and
a first microlens for redirecting incident light toward the light incidence surface of the corresponding photoelectric conversion part via the first transmission filter,
wherein a second pixel of the pixel unit includes:
a second transmission filter having a higher transparency than the first transmission filter, the second transmission filter being provided on a light incidence path leading to a light incidence surface of a corresponding photoelectric conversion part; and
a second microlens for redirecting incident light toward the light incidence surface of the corresponding photoelectric conversion part via the second transmission filter, and
wherein a second incident light redirecting region handled by the second microlens is greater than a first incident light redirecting region handled by the first microlens.

2. The solid-state imaging device of claim 1, wherein the second microlens has a greater diameter than the first microlens in a direction parallel to the light incidence surface of the photoelectric conversion part.

3. The solid-state imaging device of claim 2, wherein the second microlens of the second pixel extends radially beyond a region of the second pixel over a region of the first pixel adjacent to the second pixel adjacent to the second pixel.

4. The solid-state imaging device of claim 3, wherein the second microlens is shaped like a polyhedron having extended portions that are equally extended in respective extending directions.

5. The solid-state imaging device of claim 1, wherein a unit color matrix is formed by pixels of at least two adjacent pixel units.

6. The solid-state imaging device of claim 5, wherein the unit color matrix includes, as the second transmission filters, W (clear, mono) filters that are highly transparent for enhanced responsiveness.

7. The solid-state imaging device of claim 5, wherein the unit color matrix includes, as the first transmission filters, IR filters for background light subtraction and/or specific optical imaging.

8. The solid-state imaging device of claim 1,
wherein the pixel part has sharing pixels arranged therein,
wherein each of the sharing pixels has:
at least two photoelectric conversion elements for storing therein charges generated by photoelectric conversion;
at least two transfer elements for individually transferring the charges stored in the respective photoelectric conversion elements; and
a floating diffusion to which the charges stored in each of the photoelectric conversion elements are transferred through a corresponding one of the transfer elements,
wherein one floating diffusion is shared between the photoelectric conversion elements and between the transfer elements, and
wherein a first saturation signal from one of the photoelectric conversion elements is transferred to the floating diffusion via one of the transfer elements, and
wherein a second saturation signal from a different one of the photoelectric conversion elements is discharged to a region that is different from a region of the floating diffusion.

9. The solid-state imaging device of claim 8, wherein each of the sharing pixels has, for each of the photoelectric conversion elements, two control gates serving as a discharge gate and a transfer gate, so that the stored charges are discharged to independently control a duration of integration.

10. The solid-state imaging device of claim 8,
wherein each of the sharing pixels has color filters arranged correspondingly to the photoelectric conversion elements, and
wherein a high-transmittance color filter is applied to a first photoelectric conversion element from which overflow photo charges are stored in the floating diffusion, and a low-transmittance color filter is applied to a second photoelectric conversion element in which generated photo charges are accumulated and stored as a read-out signal.

11. The solid-state imaging device of claim 10, wherein, in each of the sharing pixels, the high-transmittance color filter is allocated to the first photoelectric conversion element to increase a signal response coverage to such an extent that all signals from the first photoelectric conversion element are saturated, as a result of which the low-transmittance color filter is allocated to the second photoelectric conversion element.

12. The solid-state imaging device of claim 8, wherein a full well capacity of a high-transmittance photoelectric conversion element in each of the sharing pixels in which overflow charges are stored is increased.

13. The solid-state imaging device of claim 12, comprising
a reading part for reading a pixel signal from each of the sharing pixels in the pixel part,
wherein the reading part performs a sequence of operations to read the pixel signal from each of the sharing pixels,
starting with a read-out operation of a read-out signal (Qpd0) from the first photoelectric conversion element,
subsequently performing a read-out operation of an overflow signal (Qfd), so that a total amount of photo charges to be processed is extended, and
subsequently performing a read-out operation of a read-out signal (Qpd1) from the second photoelectric conversion element, and
wherein a total amount of photo charges is determined by photo charges (Qpd0+Qfd) from the first photoelectric conversion element and photo charges Qpd1 from the second photoelectric conversion element.

14. The solid-state imaging device of claim 13, wherein the reading part is configured to perform global read-out using pixel-wise analog sample-and-hold circuits or analog-to-digital conversions (ADCs) for respective signal sequences having a plurality of operation sequences.

15. The solid-state imaging device of claim 14, wherein each of the sharing pixels has:
a storage element connected to the floating diffusion; and
a storage capacitance element for storing the charges received from the floating diffusion via the storage element.

16. A method for manufacturing a solid-state imaging device, the solid-state imaging device including a pixel part having an array of pixels arranged therein, each of the pixels including a photoelectric conversion part and being configured to perform photoelectric conversion on light incident thereon,
wherein, in the pixel part, at least two adjacent pixels of the pixels form a pixel unit,
wherein a first pixel of the pixel unit includes:
a first transmission filter having a predetermined transparency, the first transmission filter being provided on a light incidence path leading to a light incidence surface of a corresponding photoelectric conversion part; and
a first microlens for redirecting incident light toward the light incidence surface of the corresponding photoelectric conversion part via the first transmission filter,
wherein a second pixel of the pixel unit includes:
a second transmission filter having a higher transparency than the first transmission filter, the second transmission filter being provided on a light incidence path leading to a light incidence surface of a corresponding photoelectric conversion part; and
a second microlens for redirecting incident light toward the light incidence surface of the corresponding photoelectric conversion part via the second transmission filter, and
wherein a second incident light redirecting region handled by the second microlens is greater than a first incident light redirecting region handled by the first microlens.

17. An electronic apparatus comprising:
a solid-state imaging device; and
an optical system for forming a subject image on the solid-state imaging device,
wherein the solid-state imaging device includes a pixel part having an array of pixels arranged therein, each of the pixels including a photoelectric conversion part and being configured to perform photoelectric conversion on light incident thereon,
wherein, in the pixel part, at least two adjacent pixels of the pixels form a pixel unit,
wherein a first pixel of the pixel unit includes:
a first transmission filter having a predetermined transparency, the first transmission filter being provided on a light incidence path leading to a light incidence surface of a corresponding photoelectric conversion part; and
a first microlens for redirecting incident light toward the light incidence surface of the corresponding photoelectric conversion part via the first transmission filter,
wherein a second pixel of the pixel unit includes:
a second transmission filter having a higher transparency than the first transmission filter, the second transmission filter being provided on a light incidence path leading to a light incidence surface of a corresponding photoelectric conversion part; and
a second microlens for redirecting incident light toward the light incidence surface of the corresponding photoelectric conversion part via the second transmission filter, and
wherein a second incident light redirecting region handled by the second microlens is greater than a first incident light redirecting region handled by the first microlens.
